(19) United States
(12) Patent Application Publication
(10) Pub. No.: US 2024/0122046 A1
(43) Pub. Date: Apr. 11, 2024

(54) LIGHT EMITTING DISPLAY APPARATUS

(71) Applicant: LG Display Co., Ltd., Seoul (KR)

(72) Inventors: HyunHaeng LEE, Paju-si (KR); DuHwan OH, Paju-si (KR)

(73) Assignee: LG Display Co., Ltd., Seoul (KR)

(21) Appl. No.: 18/377,026

(22) Filed: Oct. 5, 2023

(30) Foreign Application Priority Data
Oct. 7, 2022 (KR) 10-2022-0128537

(51) Int. Cl. H10K 59/80; H10K 59/35

(52) U.S. Cl. CPC H10K 59/8791; H10K 59/351

(57) ABSTRACT

A light emitting display apparatus may include a substrate, a plurality of pixels having a plurality of subpixels on the substrate, a light extraction portion disposed on the substrate and in each of the plurality of subpixels, and a light emitting device layer on the light extraction portion. The light extraction portion may include a plurality of concave portions and a convex portion between the plurality of concave portions. A tilt line passing through a center portion of each of the plurality of concave portions at one or more of the plurality of subpixels may be inclined from a straight line parallel to a length direction of the substrate.

### CROSS-REFERENCE TO RELATED APPLICATIONS

This application claims the benefit of and priority to Korean Patent Application No. 10-2022-0128537, filed on Oct. 7, 2022, the entirety of which is incorporated herein by reference for all purposes.

### 1. TECHNICAL FIELD

The present disclosure relates to a display apparatus and particularly to, for example, without limitation, a light emitting display apparatus.

### 2. DISCUSSION OF THE RELATED ART

A light emitting display device exhibits a high response speed while maintaining low power consumption. Unlike a liquid crystal display device, the light emitting display device is a self-emissive display device and does not require a separate light source. Thus, there is typically no problem with the viewing angle. Accordingly, a light emitting display device has received attention as a next generation flat panel display device.

A light emitting display device displays an image through light emission of an emitting device layer including an emission layer interposed between two electrodes.

However, since some of the light emitted from the emitting device layer is not emitted to the outside due to total reflection at the interface between the emitting device layer and the electrode and/or total reflection at the interface between the substrate and the air layer, the light extraction efficiency is reduced. Accordingly, the emitting display device has problems in that brightness is reduced due to low light extraction efficiency, and power consumption is increased.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

One or more aspects of the present disclosure are directed to providing a light emitting display device that substantially obviates one or more problems due to limitations and disadvantages of the related art.

An aspect of the present disclosure is directed to providing a light emitting display apparatus in which a stain pattern of reflected light, occurring due to the multi-interference and/or constructive interference of light caused by the reflection of external light, may be minimized or reduced.

Another aspect of the present disclosure is directed to providing a light emitting display apparatus in which the occurrence of a radial-shaped rainbow pattern and a radial-shaped circular ring pattern, based on a diffraction pattern of reflected light occurring due to the multi-interference and/or constructive interference of light caused by the reflection of external light, may be minimized or reduced.

Yet another aspect of the present disclosure is to provide a light emitting display apparatus capable of reducing degradation of black visibility characteristics caused by reflection of external light.

The aspects of the present disclosure are not limited to the aforesaid, but other aspects not described herein will be clearly understood by those skilled in the art from the description herein.

To achieve these and other aspects of the present disclosure, as embodied and broadly described herein, in one or more aspects, a light emitting display apparatus may include a substrate; a plurality of pixels having a plurality of subpixels on the substrate; a light extraction portion disposed on the substrate and in each of the plurality of subpixels; and a light emitting device layer on the light extraction portion. The light extraction portion may include a plurality of concave portions and a convex portion between the plurality of concave portions, and a tilt line passing through a center portion of each of the plurality of concave portions at one or more of the plurality of subpixels may be inclined from a straight line parallel to a length direction of the substrate.

According to one or more example embodiments of the present disclosure, an angle between the straight line and the tilt line may be more than 0 degrees and less than 60 degrees.

According to one or more example embodiments of the present disclosure, the light extraction portion may have rotated with respect to a reference point within a corresponding subpixel.

According to one or more example embodiments of the present disclosure, the light extraction portion may have rotated by an angle of more than 0 degrees and less than 60 degrees with respect to a center portion of one of a plurality of concave portions of a corresponding subpixel.

In the light emitting display apparatus according to one or more example embodiments of the present specification, the light extraction efficiency of light which is emitted from a light emitting device layer may be improved.

In a light emitting display apparatus according to one or more example embodiments of the present disclosure, a tilt line passing through center portions of concave portions of a light extraction portion in one or more of a plurality of subpixels may be inclined with respect to a straight line parallel to a length direction of a substrate, and thus, a diffraction pattern of reflected light occurring in the light extraction portion may be offset or minimized, or the occurrence of a radial-shaped rainbow pattern and a radial-shaped circular ring pattern of the reflected light caused by the irregularity or randomness of the diffraction pattern of the reflected light may be prevented or minimized.

In the light emitting display device according to one or more example embodiments of the present disclosure, the degradation of black visibility characteristics by the reflection of external light may be reduced, thereby a real black in a non-driving or turning-off state may be realized.

Other aspects, features and advantages of the present disclosure are set forth in the present disclosure and will also be apparent from the present disclosure or may be learned by practice of the inventive concepts provided herein. Other aspects, features and advantages of the present disclosure may be realized and attained by the descriptions provided in the present disclosure, including the claims and the drawings.

Furthermore, other devices, methods, features and advantages will be, or will become, apparent to one with skill in the art upon examination of the drawings and detailed description herein. It is intended that all such devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are exemplary and explanatory, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles of the disclosure.

FIG. 1 is a view schematically illustrating a light emitting display apparatus according to an example embodiment of the present disclosure.

FIG. 2 is an example of a cross-sectional view illustrating one subpixel shown in FIG. 1.

FIG. 3 is a plan view illustrating an example of a portion of a light extraction portion shown in FIG. 2.

FIG. 4 is a view illustrating a reflection phenomenon of external light caused by a light extraction portion in a light emitting display apparatus according to an example embodiment of the present disclosure.

FIG. 5 is a view schematically illustrating one subpixel shown in a light emitting display apparatus according to another example embodiment of the present disclosure.

FIG. 6 is an example of an enlarged view of part “A” shown in FIG. 5.

FIG. 7 is an example of a cross-sectional view taken along line I-I′ shown in FIG. 5.

FIG. 8 is a diagram illustrating a reflection phenomenon of external light by a light extraction portion, in a light emitting display apparatus according to another example embodiment of the present disclosure.

FIG. 9 is a diagram illustrating a plurality of pixel blocks provided in a light emitting display apparatus according to another example embodiment of the present disclosure.

FIG. 10A is an example of a diagram illustrating a rotation structure of a pixel-based light extraction portion disposed in one pixel block shown in FIG. 9.

FIG. 10B is an example of an enlarged view of a light extraction portion provided in a pixel group at the first row and the jth column shown in FIG. 10A.

FIG. 10C is an example of an enlarged view of a light extraction portion provided in a pixel group at the second row and the jth column shown in FIG. 10A.

FIG. 11 is an example of a diagram illustrating a rotation structure of a pixel group-based light extraction portion disposed in one pixel block shown in FIG. 9.

FIG. 12 is an example of a diagram illustrating a rotation structure of a subpixel-based light extraction portion disposed in one pixel block shown in FIG. 9.

FIG. 13 is an example of a diagram illustrating four subpixels shown in FIG. 12.

FIG. 14A is an example of a diagram illustrating a light extraction portion of a first subpixel shown in FIG. 13.

FIG. 14B is an example of a diagram illustrating a light extraction portion of a second subpixel shown in FIG. 13.

FIG. 14C is an example of a diagram illustrating a light extraction portion of a third subpixel shown in FIG. 13.

FIG. 14D is an example of a diagram illustrating a light extraction portion of a fourth subpixel shown in FIG. 13.

FIG. 15 is a diagram illustrating one pixel in a light emitting display apparatus according to another example embodiment of the present disclosure.

FIG. 16A is a photograph illustrating black visibility characteristics of the light emitting display apparatus according to an example embodiment of the present disclosure shown in FIG. 2.

FIG. 16B is a photograph illustrating black visibility characteristics of the light emitting display apparatus according to another example embodiment of the present disclosure shown in FIG. 5.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure. Further, the present disclosure is defined by the scope of claims and their equivalents.

Shapes, dimensions (e.g., sizes, lengths, widths, heights, thicknesses, locations, radii, diameters, and areas), ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements, one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two elements (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of” or the like, one or more other elements may be located between the two elements unless a more limiting term, such as “immediate(ly),” “direct(ly),” or “close(ly),” is used. For example, when an element is described as being positioned “on,” “on a top of,” “upon,” “on top of,” “over,” “under,” “above,” “below,” “beneath,” “near,” “close to,” “adjacent to,” “beside,” “next to,” or “at or on a side of” another element, this description should be construed as including a case in which the elements contact each other directly as well as a case in which one or more additional elements are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, regions, components, sections, or the like), these elements should not be limited by these terms, for example, to any particular order, precedence, or number of elements. These terms are used only to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, or the like) is “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phase that an element (e.g., layer, film, region, component, section, or the like) is “provided in,” “disposed in,” or the like in another element may be understood as that at least a portion of the element is provided in, disposed in, or the like in another element, or that the entirety of the element is provided in, disposed in, or the like in another element. The phrase “through” may be understood to be at least partially through or entirely through. The phase that an element (e.g., layer, film, region, component, section, or the like) “contacts,” “overlaps,” or the like with another element may be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally. For example, the terms “first direction,” “second direction,” and the like, such as the terms “first direction X,” “second direction Y,” and “diagonal direction,” should not be interpreted only based on a geometrical relationship in which the respective directions are parallel or perpendicular to each other, and may be meant as directions having wider directivities within the range within which the components of the present disclosure can operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise. In one or more aspects, unless stated otherwise, the term “nth” may refer to “nnd” (e.g., 2nd where n is 2), or “nrd” (e.g., 3rd where n is 3), and n may be a natural number.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

FIG. 1 is a view schematically illustrating a light emitting display apparatus according to an example embodiment of the present disclosure.

Referring to FIG. 1, a light emitting display apparatus according to an example embodiment of the present disclosure may include a display panel 10 and a panel driving circuit.

The display panel 10 may include a substrate 100 and a counter substrate 300 which are bonded to each other.

The substrate 100 includes a thin film transistor, and the substrate 100 may be a first substrate, a lower substrate, a transparent glass substrate, or a transparent plastic substrate. The substrate 100 or the display panel 10 may include a display area AA and a non-display area IA. The substrate 100 or the display panel 10 may have regions divided into the display area AA and the non-display area IA.

The display area AA is an area for displaying an image. The display area AA may be a pixel array area, an active area, a pixel array portion, or a screen. For example, the display area AA may be disposed at a central area of the display panel 10. The display area AA may include a plurality of pixels P.

A plurality of pixels P may each be defined as a unit area from which light is actually emitted. Each of the plurality of pixels P may include a plurality of subpixels SP. According to an example embodiment, each of the plurality of pixels P may include at least one red subpixel, at least one green subpixel, at least one blue subpixel, and at least one white subpixel, but embodiments according to the present disclosure are not limited thereto. For example, each of the plurality of pixels P may include a red subpixel, a green subpixel, a blue subpixel, and a white subpixel. Sizes of a plurality of subpixels SP included in each of the plurality of pixels P may be equal or different.

The non-display area IA is an area in which an image is not displayed. The non-display area IA may be a peripheral circuit area, a signal supply area, a non-active area, or a bezel area. The non-display area IA may be configured to surround the display area AA. The display panel 10 or substrate 100 may further include a peripheral circuit portion 120 disposed at the non-display area IA.

The peripheral circuit portion 120 may include a gate driving circuit connected to the plurality of pixels P. The gate driving circuit (or panel embedded gate driving circuit) may be integrated at one side or both sides of the non-display area IA of the substrate 100 according to a manufacturing process of a thin film transistor and may be connected to the plurality of pixels P. For example, the gate driving circuit may include a shift register already known in the art.

The counter substrate 300 may encapsulate (or seal) the display area AA disposed over the substrate 100. For example, the counter substrate 300 may be bonded to the substrate 100 using an adhesive member (or transparent adhesive). The counter substrate 300 may be an upper substrate, a second substrate, or an encapsulation substrate.

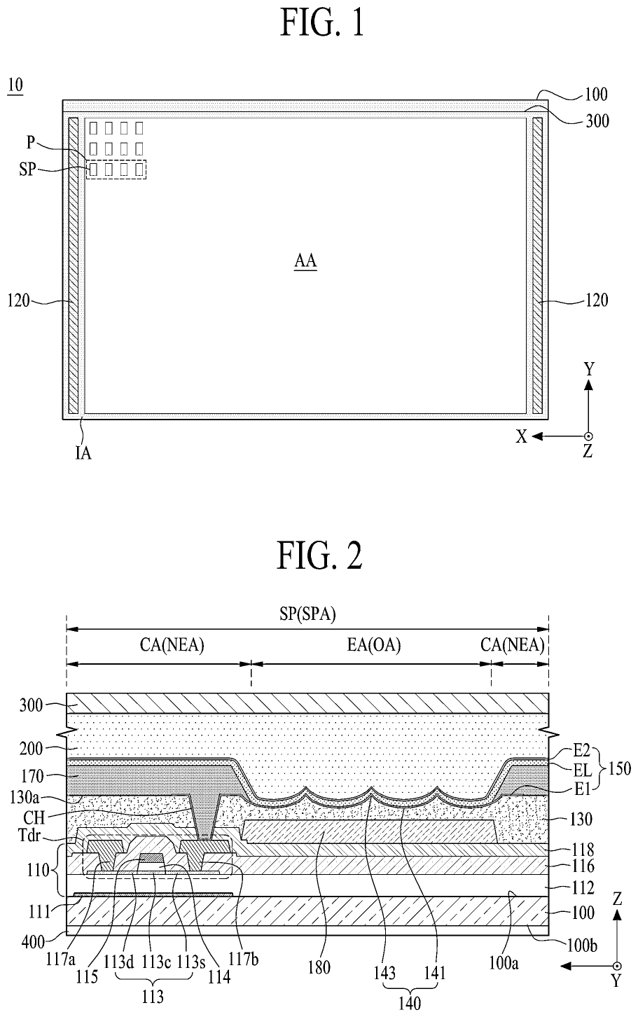

FIG. 2 is an example of a cross-sectional view illustrating one subpixel shown in FIG. 1.

Referring to FIGS. 1 and 2, the light emitting display apparatus (or a light emitting display panel) according to an example embodiment of the present disclosure may include a plurality of subpixels SP.

Each of the plurality of subpixels SP may be disposed in a corresponding one of the plurality of subpixel areas SPA disposed in the pixel P (or a pixel area). Each of the plurality of subpixel areas SPA according to an example embodiment may include a circuit area CA and an emission area EA. The circuit area CA may be spatially separated from the emission area EA within the subpixel area SPA, but embodiments according to the present disclosure are not limited thereto. For example, at least a portion of the circuit area CA may overlap with the emission area EA in the subpixel area SPA. For example, the circuit area CA may overlap the emission area EA within the subpixel area SPA, or may be disposed under (or below) the emission area EA within the subpixel area SPA. The emission area EA may be an opening region OA, a light emitting region, a light transmitting region, or a light transmitting portion. For example, the circuit area CA may be a non-emission area NEA or a non-opening area. The subpixel area SPA according to another example embodiment may further include a transparent portion (or a light transmitting portion) disposed around at least one of the emission area EA and the circuit area CA. For example, the one pixel P may include an emission area for each subpixel corresponding to a respective one of the plurality of subpixels SP, and a transparent portion (or a light transmitting portion) disposed around a respective one of the plurality of subpixels SP. In this case, the light emitting display apparatus may implement a transparent light emitting display apparatus due to light transmission of the transparent portion.

The light emitting display apparatus (or a light emitting display panel) according to an example embodiment of the present disclosure may include a pixel circuit layer 110, a protection layer 130, and a light emitting device layer 150 which are disposed over the substrate 100.

The pixel circuit layer 110 may include a buffer layer 112, a pixel circuit, and a passivation layer 118.

The buffer layer 112 may be disposed at the entirety of a first surface (or a front surface) 100a of the substrate 100. The buffer layer 112 may prevent or at least reduce materials contained in the substrate 100 from spreading to a transistor layer during a high-temperature process in the manufacturing of the thin film transistor, or may prevent external water or moisture from permeating into the light emitting device layer 150. For example, the buffer layer 112 may be a first insulating layer, a first inorganic material layer, or a lowermost insulating layer from of a plurality of insulating layers disposed at the pixel circuit layer of the substrate 100.

The pixel circuit may include a driving thin film transistor Tdr disposed in a circuit area CA of each subpixel SP (or each subpixel areas SPA). The driving thin film transistor Tdr may include an active layer 113, a gate insulating layer 114, a gate electrode 115, an interlayer insulating layer 116, a drain electrode 117a, and a source electrode 117b.

The active layer 113 may be configured with a semiconductor material based on any one of amorphous silicon, polycrystalline silicon, oxide, and organic materials.

The gate insulating layer 114 may be formed over a channel region 113c of the active layer 113. In an example embodiment, the gate insulating layer 114 may be formed having an island shape over the channel region 113c of the active layer 113, or may be formed over the entire front surface of the buffer layer 112 or substrate 100 including the active layer 113. For example, when the gate insulating layer 114 is formed at the entire front surface of the buffer layer 112, the gate insulating layer 114 may be a second insulating layer, a second inorganic material layer, or a lowermost middle insulating layer of a plurality of insulating layers disposed at the pixel circuit layer of the substrate 100.

The gate electrode 115 may be disposed over a gate insulating layer 114 to overlap a channel region 113c of an active layer 113.

The interlayer insulating layer 116 may be formed over the gate electrode 115, and a drain region 113d and a source region 113s of the active layer 113. The interlayer insulating layer 116 may be formed at the entire front surface of the buffer layer 112 or substrate 100. For example, the interlayer insulating layer 116 may be a third insulating layer, a third inorganic material layer, or an upper insulating layer of a plurality of insulating layers disposed at the pixel circuit layer of the substrate 100.

The drain electrode 117a may be disposed over the interlayer insulating layer 116 to be electrically connected to the drain region 113d of the active layer 113. The source electrode 117b may be disposed over the interlayer insulating layer 116 to be electrically connected to the source region 113s of the active layer 113.

The pixel circuit may further include first and second switching thin film transistors and at least one capacitor which are disposed at the circuit area CA together with the driving thin film transistor Tdr. The light emitting display apparatus according to an example embodiment of the present disclosure may further include a light shielding layer 111 provided under (or below) at least one active layer 113 of the driving thin film transistor Tdr, a first switching thin film transistor, and a second switching thin film transistor. The light shielding layer 111 may be configured to reduce or prevent a change in a threshold voltage of the thin film transistor caused by external light.

The passivation layer 118 may be disposed over the substrate 100 to cover (or overlay) the pixel circuit. For example, the passivation layer 118 may be configured to cover (or overlay) the drain electrode 117a and the source electrode 117b of the driving thin film transistor Tdr and the interlayer insulating layer 116. For example, the passivation layer 118 may be formed of an inorganic insulating material. The passivation layer 118 may be a fourth insulating layer, a fourth inorganic material layer, or an uppermost middle insulating layer of a plurality of insulating layers disposed at the pixel circuit layer of the substrate 100.

The protection layer 130 may be provided over the substrate 100 to cover (or overlay) the pixel circuit layer 110. The protection layer 130 may be provided at the entire display area AA and the remaining portions of the non-display area IA except the pad area. For example, the protection layer 130 may include an extension portion (or expansion portion) extended or expanded from the display area AA to the remaining portions of the non-display area IA except the pad area. Accordingly, the protection layer 130 may have a relatively large size than the display area AA.

The protection layer 130 according to an example embodiment has a relatively large thickness so that the protection layer 130 may provide an upper surface (or a planarized surface) 130a over the pixel circuit layer 110. For example, the protection layer 130 may be formed of an organic material such as one of photo acrylic, benzocyclobutene, polyimide, and/or fluorine resin, but embodiments according to the present disclosure are not limited thereto. The protection layer 130 may be a fifth insulating layer, a fifth inorganic material layer, or an uppermost insulating layer of a plurality of insulating layers disposed at the pixel circuit layer of the substrate 100, or may be a planarization layer or overcoat layer.

The protection layer 130 may include a light extraction portion 140 disposed at each subpixel P. The light extraction portion 140 may be formed at an upper surface 130a of the protection layer 130 such that the light extraction portion 140 overlaps with the emission area EA of the subpixel area SPA. The light extraction portion 140 may be formed at the protection layer 130 of the emission area EA to have a curved shape (or an uneven shape), whereby a progress path of light emitted from the light emitting device layer 150 is changed to increase light extraction efficiency of the pixel P. For example, the light extraction portion 140 may be referred to as a non-planar portion, an uneven pattern portion, a micro lens, or a light scattering pattern. In some examples, a light extraction portion may be one or more light extraction portions.

The light extraction portion 140 may include a plurality of concave portions 141, and a convex portion 143 disposed around each of the plurality of concave portions 141. Each of the plurality of concave portions 141 may be formed or configured to be concave from the upper surface 130a of the protection layer 130. The convex portion 143 may be disposed between the plurality of concave portions 141. The convex portion 143 may be formed to surround each of the plurality of concave portions 141.

A top portion of the convex portion 143 may include a sharp tip structure (or a pointed tip structure) in order to enhance light extraction efficiency of the pixel, but embodiments according to the present disclosure are not limited thereto. For example, the top portion of the convex portion 143 may have a convex curved shape. For example, the top portion of the convex portion 143 may include a dome or bell structure having a convex cross-sectional shape, but embodiments according to the present disclosure are not limited thereto.

The convex portion 143 may include an inclined portion having a curved shape between a bottom portion and the top portion. The inclined portion of the convex portion 143 may form or configure the concave portion 141. For example, the inclined portion of the convex portion 143 may be an inclined surface or a curved portion. The inclined portion of the convex portion 143 according to an example embodiment may have a cross-sectional structure having a Gaussian curve. In this case, the inclined portion of the convex portion 143 may have a tangent slope which increases progressively from the bottom portion to the top portion, and then decreases progressively.

The light emitting device layer 150 may be disposed over the light extraction portion 140 overlapping with the emission area EA. The light emitting device layer 150 may be configured to emit light toward the substrate 100 according to a bottom emission type, but embodiments according to the present disclosure are not limited thereto. The light emitting device layer 150 according to an example embodiment may include a first electrode E1, a light emitting layer EL, and a second electrode E2.

The first electrode E1 may be formed at (or over) the protection layer 130 in the subpixel area SPA, and may be electrically connected to a source electrode 117b (or a drain electrode 117a) of the driving thin film transistor Tdr. One end of the first electrode E1 which is close to the circuit area CA may be electrically connected to the source electrode 117b (or the drain electrode 117a) of the driving thin film transistor Tdr via an electrode contact hole CH provided at or passing through the protection layer 130 and the passivation layer 118.

The first electrode E1 directly contacts the light extraction portion 140 and thus, may have a shape conforming to the shape of the light extraction portion 140. As the first electrode E1 is formed (or deposited) over the protection layer 130 to have a relatively small thickness, the first electrode E1 may have a surface morphology conforming to a surface morphology of the light extraction portion 140 including the convex portion 143 and the plurality of concave portions 141. For example, the first electrode E1 is formed in a conformal shape based on the surface shape (morphology) of the light extraction portion 140 by a deposition process of a transparent conductive material, whereby the first electrode E1 may have a cross-sectional structure whose shape is the same as the light extraction portion 140.

The light emitting layer EL may be formed at (or over) the first electrode E1 and may directly contact the first electrode E1. As the light emitting layer EL is formed (or deposited) over the first electrode E1 to have a relatively large thickness in comparison to the first electrode E1, the light emitting layer EL may have a surface morphology which is different from the surface morphology in each of the plurality of concave portions 141 and the convex portion 143 or the surface morphology of the first electrode E1. For example, the light emitting layer EL may be formed in a non-conformal shape which does not conform to the surface shape (or morphology) of the first electrode E1 by a deposition process, whereby the light emitting layer EL may have a cross-sectional structure whose shape may be different from the first electrode E1.

The light emitting layer EL according to an example embodiment has a thickness that gradually increases toward the bottom surface of the convex portion 143 or the concave portion 141. For example, the light emitting layer EL may be formed of a first thickness over the top portion of the convex portion 143, may be formed of a second thickness that is thicker than the first thickness over the bottom surface of the concave portion 141, and may be formed over an inclined surface (or a curved portion) of the convex portion 143 to have a third thickness that is less than the first thickness. Herein, the first, second, and third thicknesses may be the shortest distance between the first electrode E1 and the second electrode E2, respectively.

The light emitting layer EL may include two or more organic light emitting layers configured to emit white light. As an example, the light emitting layer EL may include a first organic light emitting layer and a second organic light emitting layer to emit white light by mixing a first light and a second light. For example, the first organic light emitting layer may include any one selected of a blue organic light emitting layer, a green organic light emitting layer, a red organic light emitting layer, a yellow organic light emitting layer, and a yellow-green organic light emitting layer to emit the first light. For example, the second organic light emitting layer may include an organic light emitting layer capable of emitting the second light to obtain white light in the light emitting layer EL by mixing the first light of a blue organic light emitting layer, a green organic light emitting layer, a red organic light emitting layer, a yellow organic light emitting layer, or a yellow-green organic light emitting layer. The light emitting layer EL according to another example embodiment may include any one selected of a blue organic light emitting layer, a green organic light emitting layer, and a red organic light emitting layer. Additionally, the light emitting layer EL may include a charge generating layer interposed between the first organic light emitting layer and the second organic light emitting layer.

The second electrode E2 may be formed at (or over) the light emitting layer EL and may directly contact the light emitting layer EL. The second electrode E2 may be formed (or deposited) at (or over) the light emitting layer EL to have a relatively smaller thickness compared to the light emitting layer EL. The second electrode E2 may be formed (or deposited) at (or over) the light emitting layer EL to have a relatively small thickness, and thus may have a surface morphology corresponding to the surface morphology of the light emitting layer EL. For example, the second electrode E2 may be formed in a conformal shape corresponding to the surface shape (or morphology) of the light emitting layer EL by a deposition process, whereby the second electrode E2 may have the same cross-sectional structure as the light emitting layer EL and may have a cross-sectional structure whose shape may be different from the light extraction portion 140.

The second electrode E2 according to an example embodiment may include a metal material having a high reflectance to reflect the incident light emitted from the light emitting layer EL toward the substrate 100. For example, the second electrode E2 may include a single-layered structure or multi-layered structure of any one material selected of aluminum (Al), argentums (Ag), molybdenum (Mo), aurum (Au), magnesium (Mg), calcium (Ca), or barium (Ba), or alloy of two or more materials selected from aluminum (Al), argentums (Ag), molybdenum (Mo), aurum (Au), magnesium (Mg), calcium (Ca), or barium (Ba). The second electrode E2 may include an opaque conductive material having high reflectance. For example, the second electrode E2 may include a reflection electrode, a cathode electrode, a light reflection surface, or a light reflective portion, and in this case, the first electrode may be an anode electrode or a transparent electrode.

As described above, the light emitting device layer 150 may generate light responsive to current supplied thereto through the pixel circuit and thus, may emit light. The concave portion 141 or the convex portion 143 of the light extraction portion 140 changes the travel path of the light emitted from the light emitting layer EL to the light emitting surface (or a light extraction surface or a rear surface) 100b, to thereby increase the external extraction efficiency of the light emitted from the light emitting layer EL. For example, the convex portion 143 prevents or reduces degradation of the light extraction efficiency caused by the light which is trapped in the light emitting device layer 150 by repeating total reflection between the first electrode E1 and the second electrode E2 of the light emitting device layer 150 without traveling to the light emitting surface 100b. Accordingly, in the light emitting display apparatus according to an example embodiment of the present disclosure, the light extraction efficiency of light emitted from the light emitting device layer 150 may be enhanced.

The light emitting display apparatus according to an example embodiment of the present disclosure may further include a bank layer 170. The bank layer 170 may be disposed over an edge portion of the first electrode E1 and the protection layer 130. The bank layer 170 may be formed of an organic material such as benzocyclobutene (BCB)-based resin, acrylic-based resin, polyimide resin, or the like.

The bank layer 170 may be disposed over the upper surface 130a of the protection layer 130 to cover (or overlay) the edge portion of the first electrode E1 extending onto the circuit area CA. The emission area EA defined by the bank layer 170 may be smaller in size than the light extraction portion 140 of the protection layer 130 in a two-dimensional structure.

The light emitting layer EL of the light emitting device layer 150 may be provided over the first electrode E1, the bank layer 170, and a step difference portion between the first electrode E1 and the bank layer 170. In this case, when the light emitting layer EL is provided with a small thickness at the step difference portion between the first electrode E1 and the bank layer 170, an electrical contact (or short) may occur between the second electrode E2 and the first electrode E1 due to a thickness reduction of the light emitting layer EL. To prevent this problem, one end (or an outermost bank line) of the bank layer 170 adjacent to the emission area EA may be disposed to cover (or overlay) the edge portion of the light extraction portion 140 to reduce a step difference between the first electrode E1 and the bank layer 170. Therefore, the electric contact (or short) between the first electrode E1 and the second electrode E2 may be prevented due to the end of the bank layer 170 disposed at the step difference portion between the first electrode E1 and the bank layer 170.

The light emitting display apparatus according to an example embodiment of the present disclosure may further include a color filter layer 180.

The color filter layer 180 may be disposed between the substrate 100 and the protection layer 130 to overlap with at least one emission area EA. The color filter layer 180 according to an example embodiment may be disposed between the passivation layer 118 and the protection layer 130 to overlap with the emission area EA. The color filter layer 180 according to another example embodiment may be disposed between the substrate 100 and the interlayer insulating layer 116 or between the interlayer insulating layer 116 and the passivation layer 118 to overlap with the emission area EA.

The color filter layer 180 may have a larger size than the emission area EA. For example, the color filter layer 180 may be larger than the emission area EA, and may be smaller than the light extraction portion 140 of the protection layer 130, but embodiments according to the present disclosure are not limited thereto, and the color filter layer 180 may be larger than the light extraction portion 140. For example, when the color filter layer 180 has a greater size than the light extraction portion 140, light leakage through which internal light travels toward the adjacent subpixel SP may be reduced or minimized.

The color filter layer 180 according to an example embodiment may include a color filter which transmits the wavelength of a color set in the subpixel SP of the light emitted (or extracted) from the light emitting device layer 150 toward the substrate 100. For example, the color filter layer 180 may transmit the red wavelength, green wavelength, or blue wavelength. When the one pixel comprises adjacent first to fourth subpixels SP, the color filter layer provided at the first subpixel may include a red color filter, the color filter layer provided at the second subpixel may include a green color filter, and the color filter layer provided at the third subpixel may include a blue color filter. The fourth subpixel may not include a color filter layer or may include a transparent material to compensate a step difference between adjacent pixels, thereby emitting white light.

The light emitting display apparatus (or the light emitting display panel) according to an example embodiment of the present disclosure may include an encapsulation portion 200.

The encapsulation portion 200 may be formed over the substrate 100 to cover (or overlay) the light emitting device layer 150. The encapsulation portion 200 may be formed over the substrate 100 to cover (or overlay) the second electrode E2. For example, the encapsulation portion 200 may surround the display area AA. The encapsulation portion 200 may protect the thin film transistor and the light emitting layer EL or the like from external impact and prevent oxygen or/and water (or moisture) and particles from being permeated into the light emitting layer EL.

The encapsulation portion 200 according to an example embodiment may include a plurality of inorganic encapsulation layer. Furthermore, the encapsulation portion 200 may further include at least one organic encapsulation layer interposed between the plurality of inorganic encapsulation layer. The organic encapsulation layer may be expressed as a particle overlay layer.

The encapsulation portion 200 according to another example embodiment may further include a filler (or a filling member) surrounding (or completely surrounding) the entire display area AA. In this case, the counter substrate 300 may be bonded to the substrate 100 using the filler. The filler may include a getter material that absorbs oxygen or/and water (or moisture).

The counter substrate 300 may be coupled to the encapsulation portion 200. The counter substrate 300 may be made of a plastic material, a glass material, or a metal material. For example, when the encapsulation portion 200 includes a plurality of inorganic encapsulation layers, the counter substrate 300 may be omitted.

Alternatively, when the encapsulation portion 200 is changed to a filler, the counter substrate 300 may be combined with the filler, in this case, the counter substrate 300 may be made of a plastic material, a glass material, or a metal material.

The light emitting display apparatus (or the light emitting display panel) according to an example embodiment of the present disclosure may further include a polarization member 400.

The polarization member 400 may be configured to block external light reflected by the light extraction portion 140 and the pixel circuit, or the like. For example, the polarization member 400 may be configured as a circular polarization member or a circular polarization film. The polarization member 400 may be disposed at or coupled to the light emitting surface (or a second surface or a rear surface) 100b of the substrate 100 using a coupling member (or a transparent adhesive member).

As described above, the light emitting display apparatus (or the light emitting display panel) according to an example embodiment of the present disclosure includes the light extraction portion 140 disposed or configured in the emission area EA of the subpixel SP, and thus, the path of light generated from the light emitting layer EL may be changed by the light extraction portion 140 to enhance light extraction efficiency, thereby improving luminance and reducing power consumption.

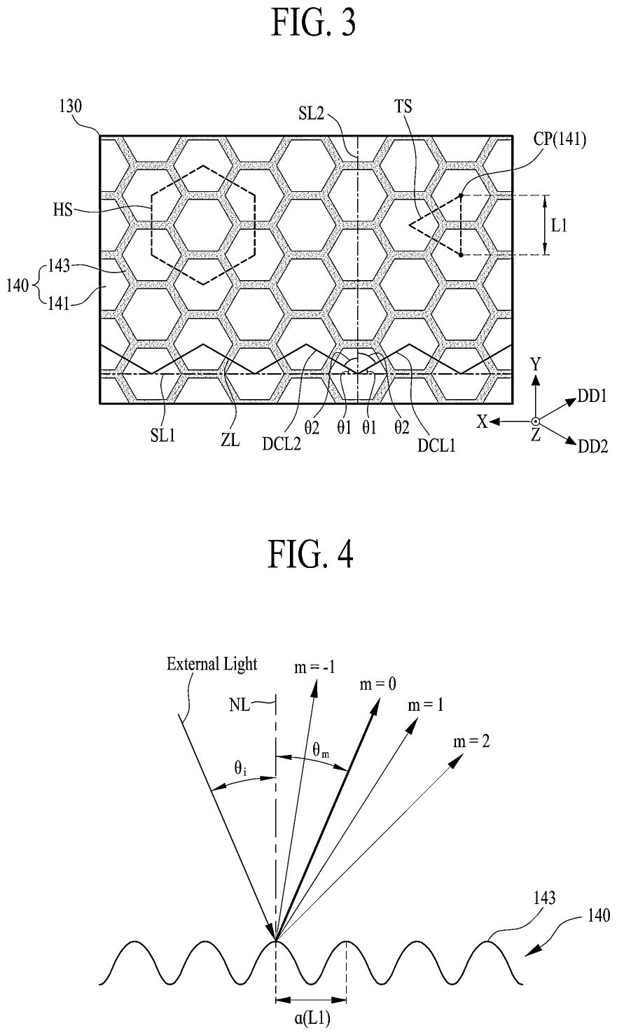

FIG. 3 is a plan view illustrating an example of a portion of a light extraction portion shown in FIG. 2. FIG. 3 is a view explaining planar structures of the concave portions and the convex portions.

Referring to FIGS. 2 and 3, the plurality of concave portions 141 according to an example embodiment of the present disclosure may be disposed in parallel to have a predetermined interval along a second direction Y and may be arranged to be staggered with one another along a first direction X intersecting the second direction Y. Thus, the light extraction portion 140 may include a larger number of concave portions 141 per unit area, thereby increasing the external extraction efficiency of the light emitted from the light emitting device layer 150. For example, the first direction X may be a first lengthwise direction of a substrate or may be a long-side lengthwise direction, a widthwise direction, or a first horizontal direction of the display panel. The second direction Y may be a second lengthwise direction of the substrate or may be a short-side lengthwise direction, a lengthwise direction, a second horizontal direction (or a vertical direction) of the display panel.

According to an example embodiment, a center portion CP of each of the plurality of concave portions 141 disposed along the first direction X may be positioned or aligned at a first straight line SL1 parallel to the first direction X. In addition, each center portion CP of a plurality of concave portions 141 disposed along the second direction Y may be positioned or aligned at a second straight line SL2 parallel to the second direction Y. For example, the first straight line SL1 may be a horizontal line or a first horizontal line, and the second straight line SL2 may be a vertical line or a second horizontal line.

According to another example embodiment, the plurality of concave portions 141 are disposed in the form of a lattice (or a grid) such that each of a plurality of concave portions 141 disposed at even-numbered horizontal lines parallel to the first direction X may be disposed between a plurality of concave portions 141 disposed at adjacent odd-numbered horizontal lines along the second direction Y. Accordingly, the plurality of concave portions 141 disposed along the second direction Y may be positioned or aligned at a zigzag line ZL having a zigzag shape along the first direction X (or the second direction Y).

According to an example embodiment, the center portion CP of each of the adjacent three concave portions 141 may be aligned to form a triangular shape TS. In addition, the center portion CP of each of the six concave portions 141 disposed around one concave portion 141 or surrounding one concave portion 141 may have a 6-angular shape HS in two-dimensions (or in a plan view). For example, each of the plurality of concave portions 141 may be disposed or arranged in a honeycomb structure, a hexagonal structure, or a circular structure in two-dimensions (or in a plan view).

According to an example embodiment of the present disclosure, when the plurality of concave portions 141 are arranged (or disposed) in a honeycomb structure, diagonal center lines DCL1 and DCL2 passing through center portions CP of concave portions arranged (or disposed) along diagonal directions DD1 and DD2 between the first direction X and the second direction Y may be respectively inclined from the first straight line SL1 and a second straight line SL2. For example, a first angle θ1 between the diagonal center lines DCL1 and DCL2 and the first straight line SL1 may be about 30 degrees, and a second angle θ2 between the diagonal center lines DCL1 and DCL2 and the second straight line SL2 may be about 60 degrees.

According to an example embodiment of the present disclosure, a pitch (or a distance) L1 between the plurality of concave portions 141 disposed at each of the plurality of subpixels SP configuring the one pixel may be equal or different from each other. The pitch L1 between the plurality of concave portions 141 may be a distance (or an interval) between the center portions CP of the two adjacent concave portions 141.

In an example embodiment, the pitch L1 between the plurality of concave portions 141 respectively disposed at a red subpixel, a green subpixel, a blue subpixel and a white subpixel may be equal or different from each other. For example, the pitch L1 between the plurality of concave portions 141 disposed at the green subpixel may be different from the pitch L1 between the plurality of concave portions 141 disposed at the blue subpixel.

In another example embodiment, the pitch L1 between the plurality of concave portions 141 disposed at the white subpixel and/or the green subpixel may be different from the pitch L1 between the plurality of concave portions 141 disposed at the red subpixel and/or the blue subpixel.

In another example embodiment, the numbers and/or densities of the plurality of concave portions 141 respectively disposed at the red subpixel, the green subpixel, the blue subpixel and the white subpixel may be equal or different from each other. For example, the numbers and/or density of the plurality of concave portions 141 disposed at the white subpixel and/or the green subpixel may be different from the number and/or density of the plurality of concave portions 141 disposed at the red subpixel and/or the blue subpixel.

The convex portion 143 may be configured to individually surround each of the plurality of concave portions 141. Accordingly, the light extraction portion 140 may include the plurality of concave portions 141 surrounded by the convex portion 143. The convex portion 143 surrounding one concave portion 141 may two-dimensionally (or in a plan view) have a hexagonal shape (or a honeycomb shape), but embodiments according to the present disclosure are not limited thereto.

FIG. 4 is a diagram illustrating a reflection phenomenon of external light by a light extraction portion, in a light emitting display apparatus according to an example embodiment of the present disclosure.

Referring to FIGS. 2 and 4, when external light is incident upon the light extraction portion 140 in a non-driving or turning-off state of the light emitting display apparatus, reflected light may be generated by a convex portion (or a flexure portion) 143 of the light extraction portion 140, and may then be emitted to the outside through the light emitting surface according to a birefringence effect of a thin film. The reflected light may cause a radial-shaped circular ring pattern and a rainbow pattern (or a rainbow stain pattern) which has a radial shape and is spread in a radial shape, based on a dispersion characteristic of light based on a wavelength-based refraction angle difference caused by a layer-based refractive index difference and a material characteristic of the light emitting device layer 150. For example, the reflected light may cause the radial-shaped rainbow pattern and the radial-shaped circular ring pattern to reduce a black visual characteristic, based on the multi-interference and/or the constructive interference of light. For example, the reflected light may generate a rainbow pattern in a radial form according to destructive interference and/or constructive interference of light, to thereby degrade black visibility characteristics. For example, the diffraction dispersion spectrum according to diffraction orders m (where m=−1, m=0, m=1, and m=2) of reflected light by the convex portion 143 of the light extraction portion 140, which serves as a diffraction grating pattern, is regularly arranged according to the reflection diffraction grating rule (or equation), whereby the rainbow pattern of the radial form may be generated. The rainbow pattern of the radial form may spread in a radial shape with respect to the convex portion of the light extraction portion 140, and the size and intensity of the light (or diffraction dispersion spectrum) diffracted according to the reflection diffraction grating rule expressed by the following Expression 1 may be varied according to a pitch L1 of the convex portion 143 of the light extraction portion 140.

α(sinθi+sinθm)=λm(m=0,±1,±2,±3, . . . ) [Expression 1]

In Expression 1, “α(alpha)” represents a pitch L1 of the convex portion (or a grating constant), “θi” represents an angle (or an angle of incidence) of incident light with respect to a normal line NL, “θm” represents an angle (or a diffraction angle) of diffracted light with respect to the normal line NL, “m” represents a diffraction order, and “λ (lambda)” represents a wavelength.

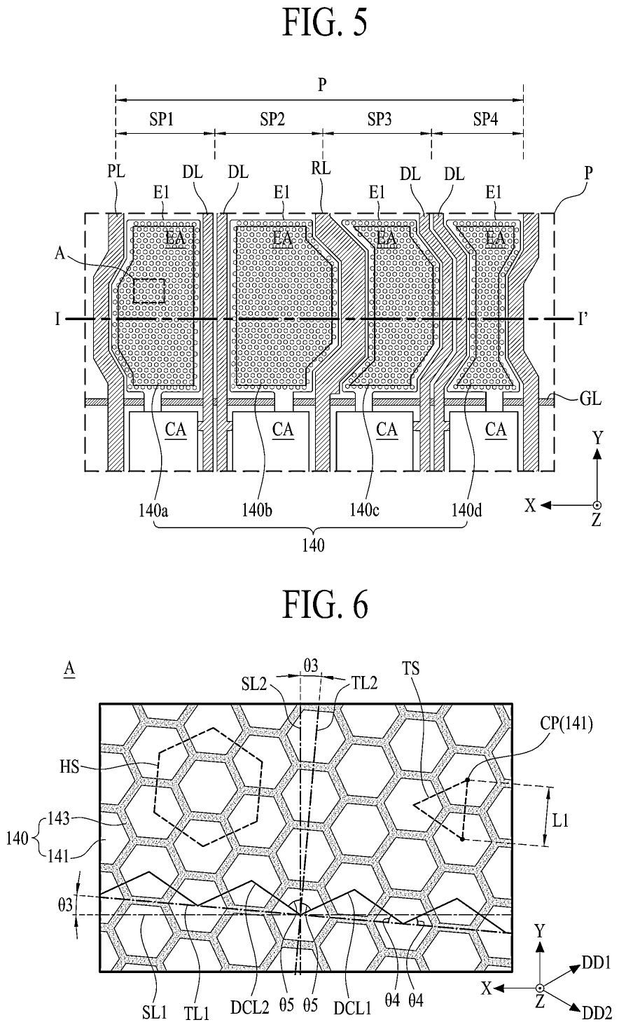

Therefore, based on various experiments, the inventors have invented a light emitting display apparatus having a new structure, which may prevent or minimize the occurrence of a radial-shaped rainbow pattern and a radial-shaped circular ring pattern to enhance a black visual characteristic. This is described below in more detail with reference to FIGS. 5 to 15.

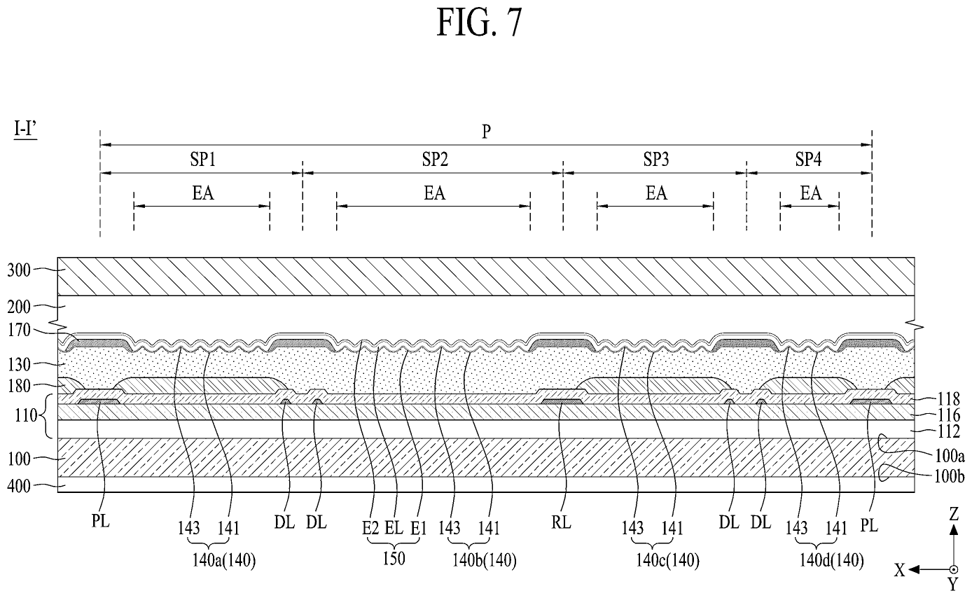

FIG. 5 is a view schematically illustrating one subpixel shown in a light emitting display apparatus according to another example embodiment of the present disclosure, FIG. 6 is an example of an enlarged view of part “A” shown in FIG. 5, and FIG. 7 is an example of a cross-sectional view taken along line I-I′ shown in FIG. 5. FIGS. 5 to 7 are diagrams for describing a light extraction portion 140 according to another example embodiment of the present disclosure. In the following description, therefore, the elements except the light extraction portion 140 and relevant elements may be referred to by like reference numerals, and their repetitive descriptions may be omitted for brevity.

Referring to FIGS. 5 to 7, in a light emitting display apparatus according to another example embodiment of the present disclosure, each of a plurality of pixels P may include four subpixels SP1 to SP4. For example, each of a plurality of pixels P may include first to fourth subpixels SP1 to SP4. For example, each of the plurality of pixels P may include a first subpixel SP1 of red, a second subpixel SP2 of white, a third subpixel SP3 of blue, and a fourth subpixel SP4 of green, but embodiments according to the present disclosure are not limited thereto.

Each of the first to fourth subpixels SP1 to SP4 may include an emission area EA and a circuit area CA. The emission area EA may be disposed at one side (or an upper side) of a subpixel area, and the circuit area CA may be disposed at the other side (or a lower side) of the subpixel area. For example, the circuit area CA may be disposed under the emission area EA with reference to a second direction Y. The emission areas EA of each of the first to fourth subpixels SP1 to SP4 may have different sizes (or areas) from each other.

The first to fourth subpixels SP1 to SP4 may be disposed adjacent to one another along a first direction X. For example, two data lines DL extending in parallel to each other along the second direction Y may be disposed between the first subpixel SP1 and the second subpixel SP2 and between the third subpixel SP3 and the fourth subpixel SP4, respectively. A gate line GL extending along the first direction X may be disposed between the emission area EA and the circuit area CA in each of the first to fourth subpixels SP1 to SP4. A pixel power line PL extending along the second direction Y may be disposed at one side of the first subpixel SP1 or the fourth subpixel SP4. A reference line RL extending along the second direction Y may be disposed between the second subpixel SP2 and the third subpixel SP3. The reference line RL may be used as a sensing line for externally sensing a variation in characteristics of a driving thin film transistor disposed in the circuit area CA of the pixel P and/or a variation in characteristics of a light emitting device layer disposed at the circuit area CA in a sensing driving mode of the pixel P.

In the light emitting display apparatus according to another example embodiment of the present disclosure, the light extraction portion 140 disposed at one or more pixels P of the plurality of pixels P may be configured to rotate (or horizontally rotate) by a predetermined angle with respect to an arbitrary reference point, so as to decrease or minimize the occurrence of a radial-shaped rainbow pattern and a radial-shaped circular ring pattern caused by the multi-interference and/or the constructive interference of reflected light in each of the plurality of pixels P. For example, the light extraction portion 140 disposed at one or more pixels P of the plurality of pixels P may rotate by a predetermined rotation angle θ3 which is greater than about 0 degrees and less than 60 degrees, with respect to an arbitrary reference point in a corresponding pixel area by units of one pixel P. For example, a rotation angle of the light extraction portion 140 disposed at each of the plurality of pixels P may be set irregularly or randomly along one or more directions of the first direction X and the second direction Y within a range of the rotation angle θ3 which is greater than about 0 degrees and less than about 60 degrees, with respect to an arbitrary reference point in a corresponding pixel area by units of the one pixel P. For example, the arbitrary reference point may be an arbitrary position within the emission area EA of each of the first to fourth subpixels SP1 to SP4 of each pixel P, or may be a center portion CP of any one of a plurality of concave portions 141.

The light extraction portion 140 according to a first example embodiment of the present disclosure may be configured to rotate (or horizontally rotate) or reversely rotate (or horizontally and reversely rotate) by the predetermined rotation angle θ3 with respect to the arbitrary reference point within the emission area EA of each of the first to fourth subpixels SP1 to SP4 of each pixel P, by units of one pixel P. For example, when the concave portions 141 of the light extraction portion 140 are arranged (or disposed) in a honeycomb structure, the concave portions 141 of the light extraction portion 140 may be configured to rotate or reversely rotate by the rotation angle θ3 which is greater than about 0 degrees and less than about 60 degrees, with respect to the arbitrary reference point within the emission area EA of each of the first to fourth subpixels SP1 to SP4. For example, the concave portions 141 of the light extraction portion 140 may be configured to rotate or reversely rotate by the rotation angle θ3 which is greater than about 0 degrees and less than about 60 degrees, with respect to a center portion CP of one concave portion 141 provided (or disposed) at the emission area EA of each of the first to fourth subpixels SP1 to SP4. For example, when the concave portions 141 of the light extraction portion 140 rotate at about 60 degrees with respect to the arbitrary reference point, the light extraction portion 140 may be configured to be equal to a case where the concave portions 141 of the light extraction portion 140 do not rotate with respect to the arbitrary reference point.

According to an example embodiment, the center portion CP of each of the plurality of concave portions 141 arranged (or disposed) at the first direction X may be positioned or aligned at a first tilt line TL1 intersecting with a first straight line SL1. In addition, the center portion CP of each of the plurality of concave portions 141 arranged (or disposed) at the second direction Y may be positioned or aligned at a second tilt line TL2 intersecting with a second straight line SL2. The first tilt line TL1 may be inclined from the first straight line SL1 by the rotation angle θ3 which is greater than about 0 degrees and less than about 60 degrees. For example, the rotation angle θ3 between the first tilt line TL1 and the first straight line SL1 and/or between the second tilt line TL2 and the second straight line SL2 may be greater than about 0 degrees and less than about 60 degrees. For example, the first tilt line TL1 may be tilted or inclined from the first straight line SL1 and may pass through the rotated center portions CP of the concave portions 141 and may be a first tilt center line or a first center extension line, and the second tilt line TL2 may be tilted or inclined from the second straight line SL2 and may pass through the rotated center portions CP of the concave portions 141 and may be a second tilt center line or a second center extension line.

According to an example embodiment of the present disclosure, when the plurality of concave portions 141 are arranged (or disposed) in a honeycomb structure and rotated with respect to the reference point, a fourth angle θ4 between the diagonal center lines DCL1 and DCL2 and the first tilt line TL1 may be about 30 degrees, and a fifth angle θ5 between the diagonal center lines DCL1 and DCL2 and the second straight line SL2 may be about 60 degrees. For example, a rotation angle (or the third angle) 03 between the first straight line SL1 and the first tilt line TL1 of the concave portions 141 or a rotation angle (or the third angle) 03 between the second straight line SL2 and the second tilt line TL2 of the concave portions 141 may be greater than about 0 degrees and less than about 60 degrees. For example, even when the plurality of concave portions 141 are rotated with respect to the reference point, each of the fourth angle θ4 and the fifth angle θ5 may be maintained to be equal to the first angle θ1 and the second angle θ2 when the concave portions 141 shown in FIG. 3 are not rotated.

The light extraction portion 140 according to an example embodiment of the present disclosure may include a first light extraction portion 140a provided (or disposed) at the first subpixel SP1 of the pixel P, a second light extraction portion 140b provided (or disposed) at the second subpixel SP2 of the pixel P, a third light extraction portion 140c provided (or disposed) at the third subpixel SP3 of the pixel P, and a fourth light extraction portion 140d provided (or disposed) at the fourth subpixel SP4 of the pixel P.

According to an example embodiment, each of the first to fourth light extraction portions 140a to 140d may be rotated or reversely rotated by the same rotation angle (or the third angle) 03 with respect to a reference point of a corresponding emission area EA or a center portion CP of one concave portion 141. The concave portion 141 of each of the first to fourth light extraction portions 140a to 140d may be rotated or reversely rotated by the same rotation angle (or the third angle) 03 with respect to a reference point of the corresponding emission area EA or the center portion CP of the one concave portion 141. Accordingly, the light extraction portion 140 provided (or configured) at each of the subpixels SP1 to SP4 of each of the plurality of pixels P may be rotated or reversely rotated by the same rotation angle (or the third angle) 03.

According to an example embodiment of the present disclosure, a rotation angle of each of the concave portions 141 of the first light extraction portion 140a, a rotation angle of each of the concave portions 141 of the second light extraction portion 140b, a rotation angle of each of the concave portions 141 of the third light extraction portion 140c, and a rotation angle of each of the concave portions 141 of the fourth light extraction portion 140d may be equal to one another. For example, the concave portions 141 of each of the first to fourth light extraction portions 140a to 140d may rotate by the same angle selected of rotation angles θ3 which are greater than about 0 degrees and less than about 60 degrees, with respect to the arbitrary reference point. Accordingly, the first to fourth light extraction portions 140a to 140d respectively provided (or configured) at the first to fourth subpixels SP1 to SP4 configuring the one pixel P may have the same shape and the same arrangement structure, and thus, diffraction patterns (or diffraction pattern distribution) of reflected lights respectively reflected from the first to fourth subpixels SP1 to SP4 configuring one pixel P may be equal to one another.

According to an example embodiment of the present disclosure, the light extraction portions 140 respectively provided (or disposed) at two adjacent pixels P of the plurality of pixels P may have different rotation angles, so as to decrease or minimize the occurrence of a radial-shaped rainbow pattern and a radial-shaped circular ring pattern caused by the multi-interference and/or the constructive interference of reflected light by the light extraction portion 140. For example, the light extraction portions 140 respectively provided (or disposed) at two pixels P adjacent to each other along one or more directions of the first direction X and the second direction Y may have different rotation angles. For example, the light extraction portions 140 respectively provided (or disposed) at two pixels P adjacent to each other in all directions may have different rotation angles.

According to an example embodiment of the present disclosure, the light extraction portions 140 respectively provided (or disposed) at two adjacent pixels P of the plurality of pixels P may have different rotation angles within a range of a rotation angle θ3 which is greater than about 0 degrees and less than about 60 degrees. Therefore, a diffraction pattern (or diffraction pattern distribution) of reflected light caused by reflection in the light extraction portion 140 disposed at each of the plurality of pixels P may be changed by pixel P units, and thus, a diffraction pattern (or diffraction pattern distribution) of reflected light occurring in the light extraction portion 140 of each of the plurality of pixels P may be offset or minimized, or a regularity of a diffraction pattern (or diffraction pattern distribution) of reflected light may be changed to irregularity or randomness, whereby the occurrence of a radial-shaped rainbow pattern and a radial-shaped circular ring pattern caused by reflected light may be prevented or minimized.

According to an example embodiment of the present disclosure, rotation angles of the light extraction portions 140 respectively disposed at two pixels P adjacent to each other of the plurality of pixels P may have a difference of 1 degree or more. The rotation angles of the light extraction portions 140 respectively disposed at two pixels P adjacent to each other along one or more directions of the first direction X and the second direction Y may have a difference of 1 degree or more. For example, rotation angles of the light extraction portions 140 respectively provided (or disposed) at two pixels P adjacent to each other in all directions may have a difference of 1 degree or more.

For example, the light extraction portion 140 disposed at an arbitrary first pixel P of the plurality of pixels P may be configured in a structure which does not rotate, and the light extraction portions 140 disposed at a second pixel P adjacent to the first pixel P may be configured to have a rotation angle of 1 degree or more or 3 degrees or more with respect to a reference point. Therefore, a radial-shaped diffraction pattern (or diffraction pattern distribution) based on reflected light in each of two adjacent pixels P may be offset or minimized by a rotation angle difference between the light extraction portions 140 respectively disposed at two adjacent pixels P, or may be prevented or minimized due to irregularity or randomness. Accordingly, a radial-shaped diffraction pattern (or diffraction pattern distribution) based on reflected light in each of the plurality of pixels P may have irregularity or randomness, based on each of different rotation angles of the light extraction portions 140 respectively provided (or configured) at the plurality of pixels P, and thus, the occurrence of a radial-shaped rainbow pattern and a radial-shaped circular ring pattern of reflected light in each of the plurality of pixels P may be prevented or minimized.

According to an example embodiment of the present disclosure, the rotation angles of the light extraction portions 140 disposed at one or more pixels P which are not adjacent to one another of the plurality of pixels P may be equal to one another or differ. For example, the rotation angles of the light extraction portions 140 disposed at two pixels P which are spaced apart from each other with two or more pixels P therebetween may be equal to one another or differ.

As described above, the light emitting display apparatus according to another example embodiment of the present disclosure may include the light extraction portion 140 rotated with respect to an arbitrary reference point at each of the plurality of pixels P, by units of the one pixel P, and thus, a diffraction pattern of reflected light caused by reflection in the light extraction portion 140 provided (or disposed) at each of the plurality of pixels P may be changed by pixel P units. Therefore, a diffraction pattern of reflected light occurring in the light extraction portion 140 of each of the plurality of pixels P may be offset or minimized, or the occurrence of a radial-shaped rainbow pattern and a radial-shaped circular ring pattern of reflected light may be prevented or minimized due to irregularity or randomness of a diffraction pattern of the reflected light. Accordingly, a reduction in a black visual characteristic occurring due to the reflection of external light in a non-driving or turning-off state of light emitting display apparatus may decrease, and thus, real black may be realized (or implemented).

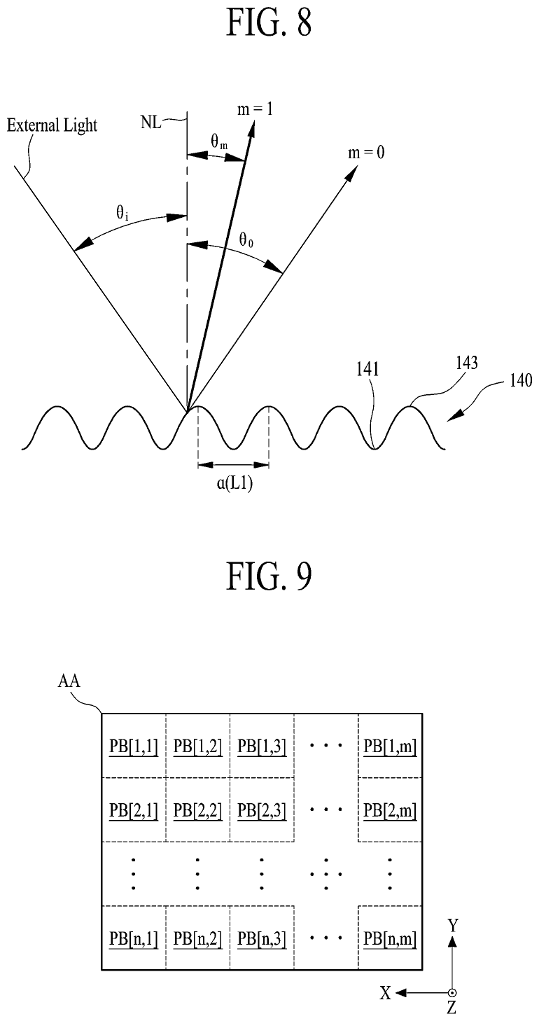

FIG. 8 is a diagram illustrating a reflection phenomenon of external light by a light extraction portion, in a light emitting display apparatus according to another example embodiment of the present disclosure.

Referring to FIG. 8, by units of one pixel P, light incident on the light extraction portion 140 which has rotated with respect to an arbitrary reference point in each of the plurality of pixels P may be reflected from a slope surface of a convex portion 143 of the rotated light extraction portion 140. The slope surface of the convex portion 143 of the rotated light extraction portion 140 may change a diffraction path of incident light to a vertical direction and may cause a diffraction pattern having maximum intensity in a specific order instead of a zeroth-order diffraction order, and thus, a diffraction pattern (or diffraction pattern distribution) caused by the light extraction portion 140 may be offset or minimized, thereby preventing or minimizing the occurrence of a radial-shaped rainbow pattern and a radial-shaped circular ring pattern caused by the light extraction portion 140.

According to an example embodiment of the present disclosure, when the light extraction portion 140 provided (or configured) at a first pixel P of two adjacent pixels P has a structure which does not rotate with respect to a reference point and the light extraction portion 140 provided (or configured) at a second pixel P adjacent to the first pixel P has a structure which has rotated with respect to the reference point, first reflected light based on the light extraction portion 140 provided in the first pixel P may have maximum intensity in a zeroth-order diffraction order as shown in FIG. 4, and second reflected light based on the light extraction portion 140 provided (or configured) at the second pixel P may have maximum intensity in a first-order diffraction order instead of the zeroth-order diffraction order by using the rotated light extraction portion 140 as shown in FIG. 8.

Therefore, due to a rotation angle difference between the light extraction portions 140 respectively provided (or disposed) at the first pixel P and the second pixel P adjacent to each other, a radial-shaped diffraction pattern (or diffraction pattern distribution) based on the first reflected light and a radial-shaped diffraction pattern (or diffraction pattern distribution) based on the second reflected light may be offset or minimized, or the occurrence of a radial-shaped rainbow pattern and a radial-shaped circular ring pattern of reflected light may be prevented or minimized due to irregularity or randomness. Accordingly, a reduction in a black visual characteristic occurring due to the reflection of external light in a non-driving or turning-off state of light emitting display apparatus may decrease, and thus, real black may be realized (or implemented).

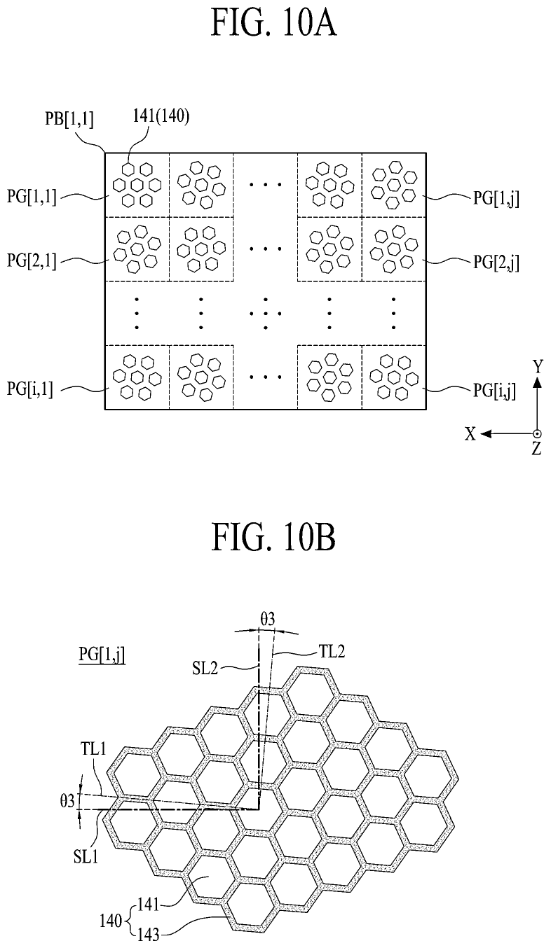

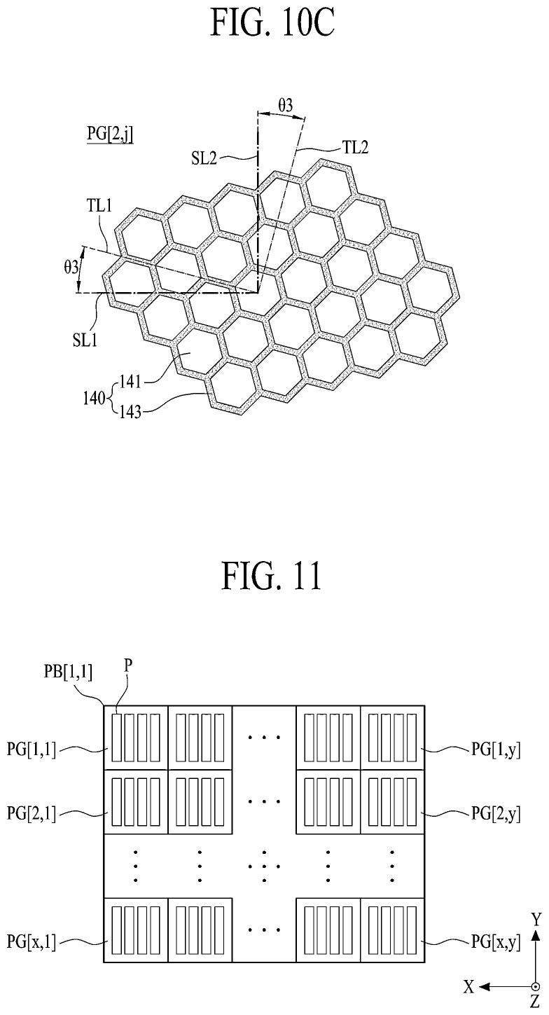

FIG. 9 is a diagram illustrating a plurality of pixel blocks provided in a light emitting display apparatus according to another example embodiment of the present disclosure, and FIG. 10A is an example of a diagram illustrating a rotation structure of a pixel-based light extraction portion disposed in one pixel block shown in FIG. 9. FIG. 10B is an example of an enlarged view of a light extraction portion provided in a pixel group at the first row and the jth column shown in FIG. 10A. FIG. 10C is an example of an enlarged view of a light extraction portion provided in a pixel group at the second row and the jth column shown in FIG. 10A.

Referring to FIGS. 9 and 10A, the light emitting display apparatus or a display area AA according to another example embodiment of the present disclosure may include a plurality of pixel blocks PB[1,1] to PB[n,m], where each of “n” and “m” is a positive integer.

The display area AA may be divided or blocked into a plurality of pixel blocks PB[1,1] to PB[n,m]. The plurality of pixel blocks PB[1,1] to PB[n,m] may be arranged (or disposed) along n number of rows and m number of columns in the display area AA. For example, the display area AA may be divided or blocked into nxm number of pixel blocks PB[1,1] to PB[n,m].

Each of the plurality of pixel blocks PB[1,1] to PB[n,m] may include a plurality of pixel groups PG[1,1] to PG[i,j]. For example, each of the plurality of pixel blocks PB[1,1] to PB[n,m] may include ixj number (or i number of rows and j number of columns) of pixel groups PG[1,1] to PG[i,j], where each of “i” and “j” is a positive integer. Each of the plurality of pixel blocks PB[1,1] to PB[n,m] may include 20 pixel groups configured as a 5×4 matrix, but embodiments according to the present disclosure are not limited thereto.

A plurality of pixels P provided (or disposed) at the display area AA may be grouped into a plurality of pixel groups PG[1,1] to PG[i,j]. For example, each of the plurality of pixel groups PG[1,1] to PG[i,j] may be configured as one pixel P. For example, the plurality of pixels P provided (or disposed) at the display area AA may be grouped (or blocked) into the ixj number (or i number of rows and j number of columns) of pixel groups and may be included in each of the plurality of pixel groups PG[1,1] to PG[i,j].

According to an example embodiment of the present disclosure, one or more of light extraction portions 140 provided (or disposed) at a pixel P of each of the plurality of pixel groups PG[1,1] to PG[ij] may be configured to rotate by a predetermined angle with respect to an arbitrary reference point within a corresponding pixel P. For example, in each of a plurality of pixel groups PG[1,1] to PG[ij], a light extraction portion 140 provided (or disposed) at each of a plurality of subpixels included in the pixel P may be configured to rotate by the predetermined angle with respect to a center portion of one concave portion 141 within a corresponding subpixel. Rotation angles of light extraction portions 140 respectively provided (or disposed) at a plurality of subpixels included in the pixel P of each of the plurality of pixel groups PG[1,1] to PG[i,j] may be equal to one another. For example, the rotation angles of light extraction portions 140 respectively provided (or disposed) at a plurality of subpixels configuring one pixel P, as shown in FIG. 5, may be equal to one another. The rotation angles of light extraction portions 140 respectively provided (or disposed) at a plurality of subpixels configuring the one pixel P may be pixel-based rotation angles. For example, a pixel-based rotation angle of a light extraction portion 140 may denote a rotation angle of a light extraction portion 140 which is identically set in each of a plurality of subpixels configuring one pixel P.

For example, the pixel-based rotation angles of light extraction portions 140 provided (or disposed) at adjacent pixel groups of the ixj number of pixel groups PG[1,1] to PG[ij] included in a pixel block PB [1,1] of 1×1 (or at the first row and the first column) may differ. For example, the pixel-based rotation angles of light extraction portions 140 provided (or disposed) at each of the i×j pixel groups PG[1,1] to PG[ij] included in the pixel block PB[1,1] of 1×1 may have a difference of 1 degree or 3 degrees or more. For example, the pixel-based rotation angles of light extraction portions 140 disposed at one or more pixel groups, which are not adjacent to one another, of the pixel groups PG[1,1] to PG[ij] included in the pixel block PB[1,1] of 1×1 may be about 0 degrees or may be equal to one another, and pixel-based rotation angles of light extraction portions 140 disposed at the other pixel groups (or remaining pixel groups) may be irregularly or randomly set within a range of more than 0 degrees and less than 60 degrees. For example, when pixel-based rotation angles between adjacent light extraction portions 140 have a difference of 3 degrees or more, the occurrence of a radial-shaped circular ring pattern occurring along with a radial-shaped rainbow pattern may be effectively prevented or minimized.

According to an example embodiment, the pixel-based rotation angles of light extraction portions 140 provided (or disposed) at each of the ixj number of pixel groups PG[1,1] to PG[i,j] corresponding to one pixel block of the plurality of pixel blocks PB[1,1] to PB[n,m] may be differently set to 1 degree or more or 3 degrees or more within a range of more than 0 degrees and less than 60 degrees. For example, the pixel-based rotation angles of light extraction portions 140 provided (or disposed) at each of the ixj number of pixel groups PG[1,1] to PG[i,j] corresponding to one pixel block of the plurality of pixel blocks PB[1,1] to PB[n,m] may be differently set to 1 degree or more or 3 degrees or more within a range of more than 0 degrees and less than 60 degrees along any one direction of a first direction, a second direction, and a diagonal direction. For example, the pixel-based rotation angles of the light extraction portions 140 provided (or disposed) at a pixel group PG[1j] of the pixel block PB[1,1] may be set to a first value. The pixel-based rotation angles of the light extraction portions 140 provided (or disposed) at a pixel group PG[2j] of the pixel block PB[1,1] may be set to a second value. The first value and the second value may be set differently so that a difference between the first and second values may be 1 degree or more or 3 degrees or more within a range of more than 0 degrees and less than 60 degrees.

According to another example embodiment, the pixel-based rotation angles of light extraction portions 140 provided (or disposed) at each of the ixj number of pixel groups corresponding to one pixel block of the plurality of pixel blocks PB[1,1] to PB[n,m] may be set to satisfy the following conditions 1 to 6 within a range of more than 0 degrees and less than 60 degrees.

Condition 1) the pixel-based rotation angles of light extraction portions 140 provided (or disposed) at each of the ixj number of pixel groups PG[1,1] to PG[i,j] may have irregularity or randomness.

Condition 2) the pixel-based rotation angles of light extraction portions 140 provided (or disposed) at two pixel groups PG[1,1] to PG[ij] directly adjacent to each other along any one direction of the first direction, the second direction, and the diagonal direction may have a difference of 1 degree or more or 3 degrees or more. In one or more aspects, this condition may be applied to all of the two adjacent pixel groups among the pixel groups PG[1,1] to PG[i,j].

Condition 3) the pixel-based rotation angles of light extraction portions 140 provided (or disposed) at pixel groups PG[1,1] to PG[ij] which are not directly adjacent to each other along any one direction of the first direction, the second direction, and the diagonal direction may be about 0 degrees.

Condition 4) two or more adjacent pixel groups PG[1,1] to PG[ij], where the pixel-based rotation angles of light extraction portions 140 have a difference of 1 degree or more or 3 degrees or more, may be disposed between pixel groups PG[1,1] to PG[i,j] where pixel-based rotation angles of light extraction portions 140 are about 0 degrees.

Condition 5) the pixel-based rotation angles of light extraction portions 140 provided (or disposed) at pixel groups PG[1,1] to PG[ij] which are not directly adjacent to each other along any one direction of the first direction, the second direction, and the diagonal direction may be equal to one another.

Condition 6) two or more adjacent pixel groups PG[1,1] to PG[i,j] where the pixel-based rotation angles of light extraction portions 140 have a difference of 1 degree or more or 3 degrees or more may be disposed between pixel groups PG[1,1] to PG[i,j] where pixel-based rotation angles of light extraction portions 140 are equal to one another.

According to an example embodiment of the present disclosure, in each of the plurality of pixel blocks PB[1,1] to PB[n,m], pixel block-based rotation angles of light extraction portions 140 provided (or disposed) at each of the ixj number of pixel groups PG[1,1] to PG[i,j] may be set differently or randomly by pixel block units. For example, the pixel block-based rotation angles of light extraction portions 140 provided (or disposed) at each of pixel blocks directly adjacent to each other along any one direction of the first direction, the second direction, and the diagonal direction among the plurality of pixel blocks PB[1,1] to PB [n,m] may have asymmetry, irregularity, or randomness. For example, the pixel block-based rotation angles of light extraction portions 140 provided (or disposed) at pixel blocks directly adjacent to each other along any one direction of the first direction, the second direction, and the diagonal direction among the plurality of pixel blocks PB[1,1] to PB[n,m] may differ entirely. For example, some of pixel block-based rotation angles of light extraction portions 140 provided (or disposed) at pixel blocks, which are not directly adjacent to each other along any one direction of the first direction, the second direction, and the diagonal direction of the plurality of pixel blocks PB[1,1] to PB[n,m] may be about 0 degrees or equal to one another. In one or more examples, a pixel block-based rotation angle of a light extraction portion 140 may denote a rotation angle of a light extraction portion 140 which is identically set in each of a plurality of subpixels configuring one pixel block.

For example, as shown in FIGS. 10B and 10C, in a pixel block PB[1,1] of 1×1 (or at a first row and a first column) shown in FIGS. 9 and 10A, a rotation angle θ3 of a light extraction portion 140 provided (or disposed) at a pixel groups PG[1j] of 1×j (or at the first row and a jth column) may differ from a rotation angle θ3 of a light extraction portion 140 provided (or disposed) at a pixel groups PG[2,j] of 2×j (or at a second row and the jth column). For example, the rotation angle θ3 of the light extraction portion 140 provided (or disposed) at the pixel groups PG[1j] of 1×j (or at the first row and the jth column) may have a difference of 1 degree or 3 degrees or more than a rotation angle θ3 of the light extraction portion 140 provided (or disposed) at a pixel groups PG[2,j] of 2×j (or at the second row and the jth column). For example, the rotation angle θ3 of the light extraction portion 140 provided (or disposed) at the pixel groups PG[1 j] of 1×j (or at the first row and the jth column) shown in FIG. 10B may be about 5 degrees. For example, the rotation angle θ3 of the light extraction portion 140 provided (or disposed) at the pixel groups PG[2,j] of 2×j (or at the second row and the jth column) shown in FIG. 10C may be about 15 degrees.

Therefore, in the light emitting display apparatus according to another example embodiment of the present disclosure, the pixel block-based rotation angles of light extraction portions 140 provided (or disposed) at each of the plurality of pixel blocks PB [1,1] to PB[n,m] and pixel-based rotation angles of light extraction portions 140 provided (or disposed) at each of the plurality of pixel groups PG[1,1] to PG[ij] included in each of the plurality of pixel blocks PB [1,1] to PB[n,m] may be set differently or randomly, and thus, a diffraction pattern of reflected light caused by reflection in the light extraction portion 140 provided (or disposed) at each of the plurality of pixels P may be changed by pixel P units. Thus, a diffraction pattern of reflected light occurring in the light extraction portion 140 of each of the plurality of pixels P may be offset or minimized, or the occurrence of a radial-shaped rainbow pattern and a radial-shaped circular ring pattern of reflected light may be prevented or minimized due to irregularity or randomness of a diffraction pattern of the reflected light. Accordingly, a reduction in a black visual characteristic occurring due to the reflection of external light in a non-driving or turning-off state of light emitting display apparatus may decrease, and thus, real black may be realized (or implemented).

FIG. 11 is an example of a diagram illustrating a rotation structure of a pixel group-based light extraction portion disposed in one pixel block shown in FIG. 9.

Referring to FIGS. 9 and 11 in conjunction with FIG. 6, in a light emitting display apparatus according to another example embodiment of the present disclosure, each of a plurality of pixel blocks PB[1,1] to PB[n,m] may include a plurality of pixel groups PG[1,1] to PG[x,y]. For example, each of the plurality of pixel blocks PB[1,1] to PB[n,m] may include xxy number (or x number of rows and y number of columns) of pixel groups PG[1,1] to PG[x,y], where each of “n” and “m” is a positive integer, and each of “i” and “j” is a positive integer.

Each of the plurality of pixel groups PG[1,1] to PG[x,y] may include four or more (or two or more) pixels P. For example, four pixels P adjacent to one another along a first direction X of a plurality of pixels P provided (or disposed) at a display area AA may be grouped into one pixel group.

According to an example embodiment of the present disclosure, in each of the plurality of pixel groups PG[1,1] to PG[x,y], light extraction portions 140 provided (or disposed) at four pixels P may be configured to rotate by a predetermined angle with respect to an arbitrary reference point within a corresponding pixel P. For example, in each of the plurality of pixel groups PG[1,1] to PG[x,y], a light extraction portion 140 provided (or disposed) at each of a plurality of subpixels included at each of four pixels P may be configured to rotate by the predetermined angle with respect to a center portion of one concave portion 141 of a corresponding subpixel. For example, pixel group-based rotation angles of light extraction portions 140 respectively provided (or disposed) at the plurality of pixel groups PG[1,1] to PG[x,y] may be equal to one another. A pixel group-based rotation angle of a light extraction portion 140 may denote a rotation angle of a light extraction portion 140 which is identically set at each of a plurality of subpixels SP (e.g., each of four subpixels) configuring one pixel group. Rotation angles of light extraction portions 140 respectively provided (or disposed) at sixteen subpixels configuring one pixel group may be equal to one another. For example, in a pixel group PG[1,1] of 1×1 (or at the first row and the first column), pixel group-based rotation angles of light extraction portions 140 respectively provided (or disposed) at a plurality of subpixels included in each of four pixels P may be equal to one another.

For example, pixel group-based rotation angles of light extraction portions 140 provided (or disposed) at adjacent pixel groups among xxy number of pixel groups PG[1,1] to PG[x,y] included in a pixel block PB[1,1] of 1×1 (or at the first row and the first column) may differ. For example, the pixel group-based rotation angles of light extraction portions 140 respectively provided (or disposed) at the xxy number of pixel groups PG[1,1] to PG[x,y] included in a pixel block PB[1,1] of 1×1 may have a difference of 1 degree or 3 degrees or more. For example, the pixel group-based rotation angles of light extraction portions 140 provided (or disposed) at one or more pixel groups, which are not adjacent to one another, of the xxy number of pixel groups PG[1,1] to PG[x,y] included in the pixel block PB [1,1] of 1×1 may be about 0 degrees or may be equal to one another, and pixel group-based rotation angles of light extraction portions 140 disposed at the other pixel groups (or remaining pixel groups) may be irregularly or randomly set within a range of more than 0 degrees and less than 60 degrees.

According to an example embodiment, the pixel group-based rotation angles of light extraction portions 140 provided (or disposed) at each of the xxy number of pixel groups PG[1,1] to PG[x,y] corresponding to one pixel block of the plurality of pixel blocks PB[1,1] to PB[n,m] may be differently set to 1 degree or more or 3 degrees or more within a range of more than 0 degrees and less than 60 degrees. For example, the pixel group-based rotation angles of light extraction portions 140 provided (or disposed) at each of the xxy number of pixel groups PG[1,1] to PG[x,y] corresponding to one pixel block of the plurality of pixel blocks PB[1,1] to PB[n,m] may be differently set to 1 degree or more or 3 degrees or more within a range of more than 0 degrees and less than 60 degrees along any one direction of a first direction, a second direction, and a diagonal direction.

According to another example embodiment, the pixel group-based rotation angles of light extraction portions 140 provided (or disposed) at each of the xxy number of pixel groups PG[1,1] to PG[x,y] corresponding to one pixel block of the plurality of pixel blocks PB[1,1] to PB[n,m] may be set to more than 0 degrees and less than 60 degrees so as to satisfy the conditions 1 to 6 described below.

Condition 1) the pixel group-based rotation angles of light extraction portions 140 provided (or disposed) at each of the xxy number of pixel groups PG[1,1] to PG[x,y] may have irregularity or randomness.

Condition 2) the pixel group-based rotation angles of light extraction portions 140 provided (or disposed) at two pixel groups PG[1,1] to PG[x,y] directly adjacent to each other along any one direction of the first direction, the second direction, and the diagonal direction may have a difference of 1 degree or more or 3 degrees or more. In one or more aspects, this condition may be applied to all of the two adjacent pixel groups among the pixel groups PG[1,1] to PG[x,y].

Condition 3) the pixel group-based rotation angles of light extraction portions 140 provided (or disposed) at pixel groups PG[1,1] to PG[x,y] which are not directly adjacent to each other along any one direction of the first direction, the second direction, and the diagonal direction may be about 0 degrees.

Condition 4) two or more adjacent pixel groups PG[1,1] to PG[x,y], where the pixel group-based rotation angles of light extraction portions 140 have a difference of 1 degree or more or 3 degrees or more, may be disposed between pixel groups PG[1,1] to PG[x,y] where pixel group-based rotation angles of light extraction portions 140 are about 0 degrees.

Condition 5) the pixel group-based rotation angles of light extraction portions 140 provided (or disposed) at pixel groups PG[1,1] to PG[x,y] which are not directly adjacent to each other along any one direction of the first direction, the second direction, and the diagonal direction may be equal to one another.

Condition 6) two or more adjacent pixel groups PG[1,1] to PG[x,y] where the pixel group-based rotation angles of light extraction portions 140 have a difference of 1 degree or more or 3 degrees or more may be disposed between pixel groups PG[1,1] to PG[x,y] where pixel group-based rotation angles of light extraction portions 140 are equal to one another.

According to an example embodiment of the present disclosure, in each of the plurality of pixel blocks PB[1,1] to PB[n,m], pixel group-based rotation angles of light extraction portions 140 provided (or disposed) at each of the xxy number of pixel groups PG[1,1] to PG[x,y] may be set differently or randomly by pixel block units. For example, the pixel group-based rotation angles of light extraction portions 140 provided (or disposed) at each of pixel blocks directly adjacent to each other along any one direction of the first direction, the second direction, and the diagonal direction among the plurality of pixel blocks PB[1,1] to PB[n,m] may have asymmetry, irregularity, or randomness. For example, the pixel group-based rotation angles of light extraction portions 140 provided (or disposed) at pixel blocks directly adjacent to each other along any one direction of the first direction, the second direction, and the diagonal direction among the plurality of pixel blocks PB[1,1] to PB[n,m] may differ entirely. For example, some of pixel group-based rotation angles of light extraction portions 140 provided (or disposed) at pixel blocks, which are not directly adjacent to each other along any one direction of the first direction, the second direction, and the diagonal direction of the plurality of pixel blocks PB[1,1] to PB[n,m] may be about 0 degrees or equal to one another.

Therefore, in the light emitting display apparatus according to another example embodiment of the present disclosure, the pixel block-based rotation angles of light extraction portions 140 provided (or disposed) at each of the plurality of pixel blocks PB [1,1] to PB[n,m] and pixel group-based rotation angles of light extraction portions 140 provided (or disposed) at each of the plurality of pixel groups PG[1,1] to PG[i,j] included in each of the plurality of pixel blocks PB[1,1] to PB[n,m] may be set differently or randomly, and thus, a diffraction pattern of reflected light caused by reflection in the light extraction portion 140 provided (or disposed) at each of the plurality of pixels P may be changed by pixel P units. Thus, a diffraction pattern of reflected light occurring in the light extraction portion 140 of each of the plurality of pixels P may be offset or minimized, or the occurrence of a radial-shaped rainbow pattern and a radial-shaped circular ring pattern of reflected light may be prevented or minimized due to irregularity or randomness of a diffraction pattern of the reflected light. Accordingly, a reduction in a black visual characteristic occurring due to the reflection of external light in a non-driving or turning-off state of light emitting display apparatus may decrease, and thus, real black may be realized (or implemented).

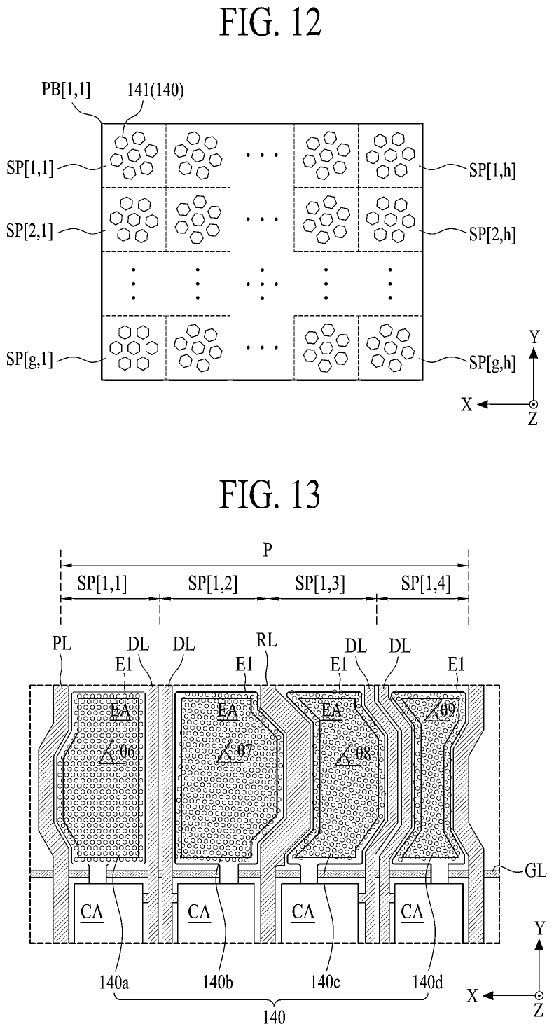

FIG. 12 is an example of a diagram illustrating a rotation structure of a subpixel-based light extraction portion disposed in one pixel block shown in FIG. 9. FIG. 13 is an example of a diagram illustrating four subpixels shown in FIG. 12.

Referring to FIGS. 9, 12, and 13, in a light emitting display apparatus according to another example embodiment of the present disclosure, each of a plurality of pixel blocks PB[1,1] to PB[n,m] may include a plurality of subpixels SP[1,1] to SP[g,h].

Each of the plurality of pixel blocks PB[1,1] to PB[n,m] may include a plurality of subpixels. For example, each of the plurality of pixel blocks PB[1,1] to PB[n,m] may include g×h number of subpixels SP[1,1] to SP[g,h]. For example, a plurality of subpixels SP provided (or disposed) at or in a display area AA may be grouped (or blocked) into g×h number (or g number of rows and h number of columns) of subpixels and may be included in each of the plurality of pixel blocks PB [1,1] to PB[n,m].

According to an example embodiment of the present disclosure, in each of the plurality of pixel blocks PB[1,1] to PB[n,m], a light extraction portion 140 provided (or disposed) at each of a plurality of subpixels SP may be configured to rotate by a predetermined angle with respect to an arbitrary reference point within a corresponding subpixel. Rotation angles of light extraction portions 140 respectively provided (or disposed) at each of the g×h number of subpixels SP[1,1] to SP[g,h] included in each of the plurality of pixel blocks PB[1,1] to PB[n,m] may differ. A rotation angle of a light extraction portion 140 provided (or disposed) at each of the plurality of subpixels SP may denote a subpixel-based rotation angle of a light extraction portion 140. For example, the subpixel-based rotation angles of light extraction portions 140 respectively provided (or disposed) at a plurality of subpixels SP included in one pixel P may differ.

For example, the subpixel-based rotation angles of light extraction portions 140 provided (or disposed) at each of the g×h number of subpixels SP[1,1] to SP[g,h] included in a pixel block PB[1,1] of 1×1 (or at the first row and the first column) may differ. For example, the subpixel-based rotation angles of light extraction portions 140 respectively provided (or disposed) at each of the g×h number of subpixels SP[1,1] to SP[g,h] included in a pixel block PB[1,1] of 1×1 may have a difference of 1 degree or 3 degrees or more. For example, the subpixel-based rotation angles of light extraction portions 140 provided (or disposed) at one or more pixel groups, which are not adjacent to one another, of the g×h number of subpixels SP[1,1] to SP[g,h] included in the pixel block PB[1,1] of 1×1 may be about 0 degrees or may be equal to one another, and subpixel-based rotation angles of light extraction portions 140 disposed at the other pixel groups (or remaining pixel groups) may be irregularly or randomly set within a range of more than 0 degrees and less than 60 degrees.

According to an example embodiment, the subpixel-based rotation angles of light extraction portions 140 provided (or disposed) at each of the g×h number of subpixels SP[1,1] to SP[g,h] corresponding to one pixel block of the plurality of pixel blocks PB[1,1] to PB[n,m] may be differently set to 1 degree or more or 3 degrees or more within a range of more than 0 degrees and less than 60 degrees. For example, the subpixel-based rotation angles of light extraction portions 140 provided (or disposed) at each of the g×h number of subpixels SP[1,1] to SP[g,h] corresponding to one pixel block of the plurality of pixel blocks PB[1,1] to PB[n,m] may be differently set to 1 degree or more or 3 degrees or more within a range of more than 0 degrees and less than 60 degrees along any one direction of a first direction, a second direction, and a diagonal direction.

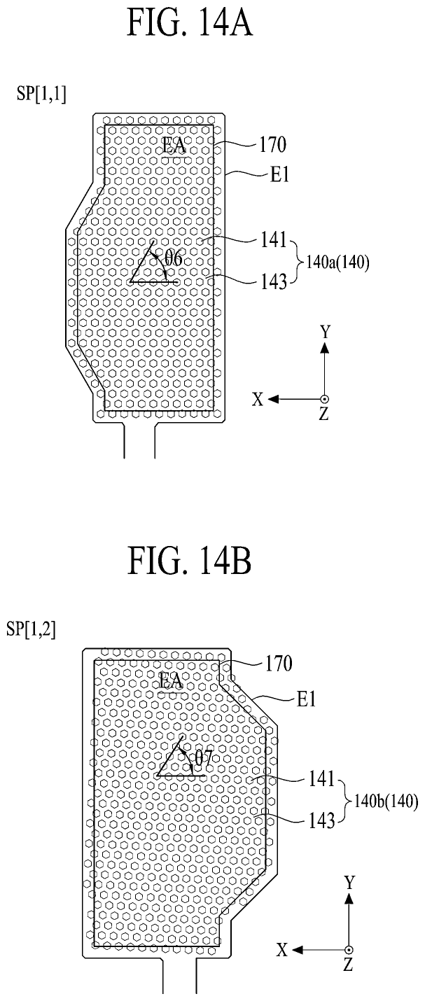

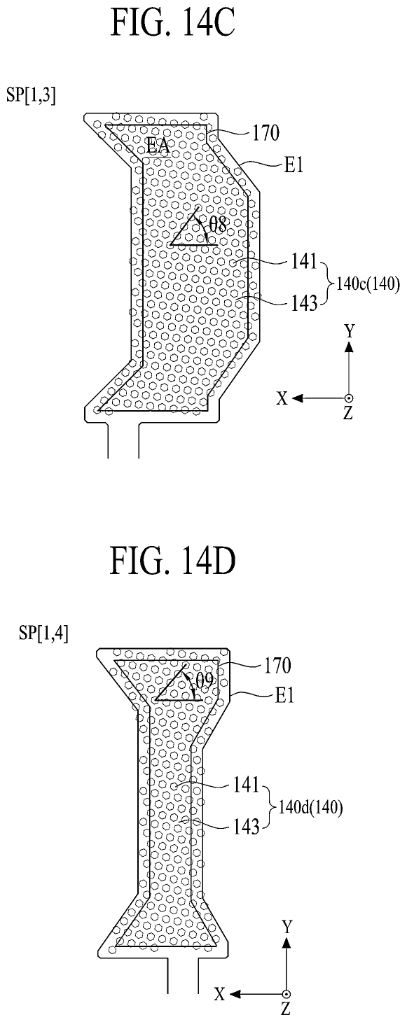

According to an example embodiment, as shown in FIG. 13, rotation angles θ6 to 09 of first to fourth light extraction portions 140a to 140d respectively provided (or disposed) at four subpixels SP[1,1] to SP[1,4] included in one pixel P may be differently set to 1 degree or more or 3 degrees or more within a range of more than 0 degrees and less than 60 degrees. For example, as shown in FIG. 14A, a rotation angle θ6 of a first light extraction portion 140a provided (or disposed) at a first subpixel SP[1,1] may be about 60 degrees or about 0 degrees where there is no rotation. For example, as shown in FIG. 14B, a rotation angle θ7 of a second light extraction portion 140b provided (or disposed) at a second subpixel SP[1,2] may be about 57 degrees. For example, as shown in FIG. 14C, a rotation angle θ8 of a third light extraction portion 140c provided (or disposed) at a third subpixel SP[1,3] may be about 53 degrees. For example, as shown in FIG. 14D, a rotation angle θ9 of a fourth light extraction portion 140d provided (or disposed) at a fourth subpixel SP[1,4] may be about 49 degrees.

According to another example embodiment, the subpixel-based rotation angles of light extraction portions 140 provided (or disposed) at each of the g×h number of subpixels SP[1,1] to SP[g,h] corresponding to one pixel block of the plurality of pixel blocks PB [1,1] to PB[n,m] may be set to more than 0 degrees and less than 60 degrees so as to satisfy the conditions 1 to 6 described below.

Condition 1) the subpixel-based rotation angles of light extraction portions 140 provided (or disposed) at each of the g×h number of subpixels SP[1,1] to SP[g,h] may have irregularity or randomness.

Condition 2) the subpixel-based rotation angles of light extraction portions 140 provided (or disposed) at two subpixels SP[1,1] to SP[g,h] directly adjacent to each other along any one direction of the first direction, the second direction, and the diagonal direction may have a difference of 1 degree or more or 3 degrees or more. In one or more aspects, this condition may be applied to all of the two adjacent subpixels among the subpixels SP[1,1] to SP[g,h].

Condition 3) the subpixel-based rotation angles of light extraction portions 140 provided (or disposed) at subpixels SP[1,1] to SP[g,h] which are not directly adjacent to each other along any one direction of the first direction, the second direction, and the diagonal direction may be about 0 degrees.

Condition 4) two or more adjacent subpixels SP[1,1] to SP[g,h], where the subpixel-based rotation angles of light extraction portions 140 have a difference of 1 degree or more or 3 degrees or more, may be disposed between subpixels SP[1,1] to SP[g,h] where subpixel-based rotation angles of light extraction portions 140 are about 0 degrees.

Condition 5) the subpixel-based rotation angles of light extraction portions 140 provided (or disposed) at subpixels SP[1,1] to SP[g,h] which are not directly adjacent to each other along any one direction of the first direction, the second direction, and the diagonal direction may be equal to one another.

Condition 6) two or more adjacent subpixels SP[1,1] to SP[g,h] where the subpixel-based rotation angles of light extraction portions 140 have a difference of 1 degree or more or 3 degrees or more may be disposed between subpixels SP[1,1] to SP[g,h] where subpixel-based rotation angles of light extraction portions 140 are equal to one another.

According to an example embodiment of the present disclosure, in each of the plurality of pixel blocks PB[1,1] to PB[n,m], subpixel-based rotation angles of light extraction portions 140 provided (or disposed) at each of the g×h number of subpixels SP[1,1] to SP[g,h] may be set differently or randomly by pixel block units. For example, the subpixel-based rotation angles of light extraction portions 140 provided (or disposed) at each of pixel blocks directly adjacent to each other along any one direction of the first direction, the second direction, and the diagonal direction among the plurality of pixel blocks PB[1,1] to PB [n,m] may have asymmetry, irregularity, or randomness. For example, the subpixel-based rotation angles of light extraction portions 140 provided (or disposed) at pixel blocks directly adjacent to each other along any one direction of the first direction, the second direction, and the diagonal direction among the plurality of pixel blocks PB[1,1] to PB[n,m] may differ entirely. For example, some of subpixel-based rotation angles of light extraction portions 140 provided (or disposed) at pixel blocks, which are not directly adjacent to each other along any one direction of the first direction, the second direction, and the diagonal direction of the plurality of pixel blocks PB[1,1] to PB[n,m] may be about 0 degrees or equal to one another.

Therefore, in the light emitting display apparatus according to another example embodiment of the present disclosure, the pixel block-based rotation angles of light extraction portions 140 provided (or disposed) at each of the plurality of pixel blocks PB [1,1] to PB[n,m] and subpixel-based rotation angles of light extraction portions 140 provided (or disposed) at each of the plurality of subpixels SP[1,1] to SP[g,h] included in each of the plurality of pixel blocks PB[1,1] to PB[n,m] may be set differently or randomly, and thus, a diffraction pattern of reflected light caused by reflection in the light extraction portion 140 provided (or disposed) at each of the plurality of pixels P may be changed by pixel P units. Thus, a diffraction pattern of reflected light occurring in the light extraction portion 140 of each of the plurality of pixels P may be offset or minimized, or the occurrence of a radial-shaped rainbow pattern and a radial-shaped circular ring pattern of reflected light may be prevented or minimized due to irregularity or randomness of a diffraction pattern of the reflected light. Accordingly, a reduction in a black visual characteristic occurring due to the reflection of external light in a non-driving or turning-off state of light emitting display apparatus may decrease, and thus, real black may be realized (or implemented).

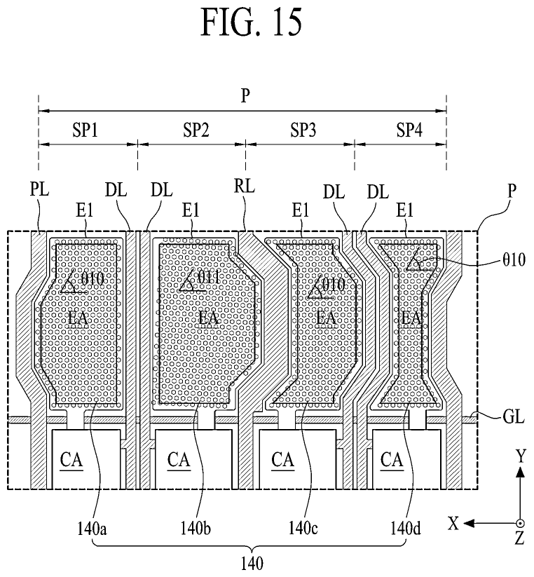

FIG. 15 is a diagram illustrating one pixel in a light emitting display apparatus according to another example embodiment of the present disclosure. FIG. 15 illustrates an example embodiment implemented by modifying a rotation angle of a light extraction portion provided in each of a plurality of subpixels included in one pixel. In the following description, therefore, only a rotation angle of a light extraction portion provided in each of a plurality of subpixels is described in more detail, and repeated descriptions may be omitted for brevity.

Referring to FIG. 15, in a light emitting display apparatus according to another example embodiment of the present disclosure, one of light extraction portions 140 respectively provided (or disposed) at or in a plurality of subpixels SP1 to SP4 included in each of a plurality of pixels P may have a different rotation angle. For example, one of light extraction portions 140 respectively provided (or disposed) at first to fourth subpixels SP1 to SP4 included in each of a plurality of pixels P may have a different rotation angle. For example, the light extraction portions 140 provided (or disposed) at the second subpixel SP2 of the first to fourth subpixels SP1 to SP4 may have a different rotation angle.

According to an example embodiment, a rotation angle of a light extraction portion 140 provided (or disposed) at some subpixels of the plurality of subpixels SP1 to SP4 included in each of the plurality of pixels P may differ from a rotation angle of a light extraction portion 140 provided (or disposed) at the other one subpixel (or remaining subpixel). For example, each of first, third, and fourth light extraction portions 140a, 140c, and 140d respectively provided (or disposed) at the first, third, and fourth subpixels SP1, SP3, and SP4 included in each of the plurality of pixels P may have the same tenth rotation angle θ10, and the second light extraction portion 140b provided (or disposed) at the second subpixel SP2 may have an eleventh rotation angle θ11. For example, the second subpixel SP2 may be a white subpixel which is relatively more in amount of reflected light than the other subpixels, but embodiments according to the present disclosure are not limited thereto.

The tenth rotation angle θ10 may be an angle which is greater than 0 degrees and less than 60 degrees. An eleventh rotation angle θ11 may be an angle which is 1 or more degrees greater than the tenth rotation angle θ10 or 3 or more degrees less than the tenth rotation angle θ10 within a range of more than 0 degrees and less than 60 degrees.

According to an example embodiment of the present disclosure, a rotation angle of the light extraction portion 140b provided (or disposed) at the second subpixel SP2 of each of the plurality of pixels P may be differently set to 1 degree or more or 3 degrees or more within a range of more than 0 degrees and less than 60 degrees. For example, a rotation angle of a light extraction portion for each second subpixel may be differently set to 1 degree or more or 3 degrees or more within a range of more than 0 degrees and less than 60 degrees along any one direction of a first direction, a second direction, and a diagonal direction.

According to another example embodiment of the present disclosure, a rotation angle of a light extraction portion for each of second subpixels spaced apart from one another with two or more pixels P therebetween along any one direction of a first direction, a second direction, and a diagonal direction may be equal within a range of more than 0 degrees and less than 60 degrees.

The pixel-based rotation angles of light extraction portions 140 of the plurality of subpixels SP1 to SP4 included in the pixel P described with reference to FIG. 15 may be identically applied to the light extraction portions 140 described above with reference to FIGS. 9 to 11, and repeated descriptions thereof are omitted.

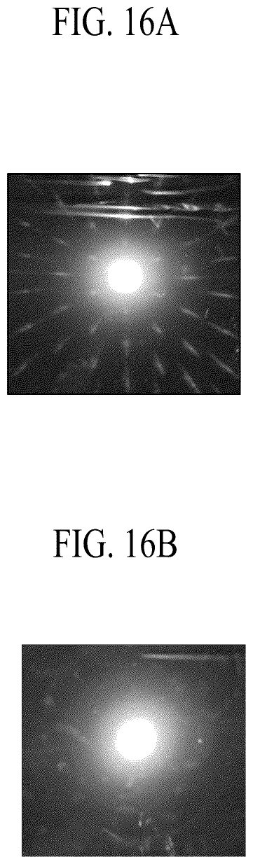

FIG. 16A is a photograph showing a black visual characteristic of the light emitting display apparatus according to an example embodiment of the present disclosure shown in FIG. 2, and FIG. 16B is a photograph showing a black visual characteristic of the light emitting display apparatus according to another example embodiment of the present disclosure shown in FIG. 5. In a light emitting display apparatus used to produce the photograph of FIG. 16A, each of light extraction portions provided in subpixels of each of a plurality of pixels has a 0-degree rotation angle. In a light emitting display apparatus used to produce the photograph of FIG. 16B, light extraction portions provided in subpixels of each of a plurality of pixels have a difference of 3 degrees or more by pixel units. In each of the light emitting display apparatuses used to produce the photographs of FIGS. 16A and 16B, no polarization member was included (or utilized).

As seen in FIG. 16A, in a light emitting display apparatus according to an example embodiment of the present disclosure, the rainbow pattern in the radial form and a radial-shaped circular ring pattern are generated by light reflected by a light extraction portion disposed at a protection layer, thereby degrading black visibility characteristics.

As seen in FIG. 16B, a light emitting display apparatus according to another example embodiment of the present disclosure may be configured so that light extraction portions provided in subpixels of each of a plurality of pixels have a difference of 3 degrees or more by pixel units, and thus, the occurrence of a radial-shaped rainbow pattern and a radial-shaped circular ring pattern of reflected light may be prevented or minimized due to a rotation angle difference between light extraction portions by pixel units, whereby it may be seen that a black visual characteristic may be enhanced.

In a modified example of FIG. 16B, where a polarization member is attached to (or included in) a light emitting display apparatus, stains having a circular ring shape occurring in a concentric circle with respect to white reflected light having a circular shape may be removed based on an antireflection function of the polarization member.

A light emitting display apparatus according to one or more example embodiments of the present disclosure is described below.

A light emitting display apparatus according to one or more example embodiments of the present disclosure may comprise a substrate, a plurality of pixels including a plurality of subpixels on the substrate, a light extraction portion disposed on the substrate and in each of the plurality of subpixels, and a light emitting device layer on the light extraction portion. The light extraction portion may comprise a plurality of concave portions and a convex portion between the plurality of concave portions, and a tilt line passing through a center portion of each of the plurality of concave portions at one or more of the plurality of subpixels may be inclined from a straight line parallel to a length direction of the substrate.

According to one or more example embodiments of the present disclosure, an angle between the straight line and the tilt line may be more than 0 degrees and less than 60 degrees.

According to one or more example embodiments of the present disclosure, the light extraction portion has rotated with respect to a reference point within a corresponding subpixel.

According to one or more example embodiments of the present disclosure, the light extraction portion have rotated by an angle of more than 0 degrees and less than 60 degrees with respect to the center portion of one of the plurality of concave portions of a corresponding subpixel.

According to one or more example embodiments of the present disclosure, a tilt line passing through center portions of the plurality of concave portions in each of the plurality of subpixels may be inclined by a different angle from the straight line. For example, an angle for the tilt line of one subpixel of the plurality of subpixels may be different from an angle for the tilt line of another subpixel of the plurality of subpixels. For example, an angle for the tilt line of each subpixel of the plurality of subpixels may be different from an angle for the tilt line of another subpixel of the plurality of subpixels. For example, one or more angles for the one or more tilt lines of one or more subpixels of the plurality of subpixels may be different from one or more angles for the one or more tilt lines of one or more other subpixels of the plurality of subpixels.

According to one or more example embodiments of the present disclosure, the tilt line passing through the center portions of the plurality of concave portions in each of the plurality of subpixels may be inclined by a different angle within a range of more than 0 degrees and less than 60 degrees from the straight line.

According to one or more example embodiments of the present disclosure, the light extraction portions of the plurality of subpixels may have rotated by different angles with respect to reference points within corresponding subpixels. For example, a rotation angle of the light extraction portion in one subpixel of the plurality of subpixels may be different from a rotation angle of the light extraction portion in another subpixel of the plurality of subpixels. For example, a rotation angle of the light extraction portion in each subpixel of the plurality of subpixels may be different from a rotation angle of the light extraction portion in another subpixel of the plurality of subpixels. For example, one or more rotation angles of one or more light extraction portions in one or more subpixels of the plurality of subpixels may be different from one or more rotation angles of one or more light extraction portions in one or more other subpixels of the plurality of sub pixels.

According to one or more example embodiments of the present disclosure, the light extraction portions in the plurality of subpixels may have rotated by different angles within a range of more than 0 degrees and less than 60 degrees with respect to the reference points within the corresponding subpixels.

According to one or more example embodiments of the present disclosure, the light emitting display apparatus may further comprise a plurality of pixel blocks including a plurality of pixel groups, and each of the plurality of pixel groups may comprise one or more of the plurality of pixels. In one or more aspects, each of the plurality of pixel blocks may comprise the plurality of pixel groups. In one or more aspects, each of the plurality of pixels may comprise the plurality of subpixels. In one or more aspects, each of the one or more of the plurality of pixels may comprise the plurality of subpixels.

According to one or more example embodiments of the present disclosure, the one or more of the plurality of pixels may comprise one or more pixels, the light extraction portion in each of the plurality of subpixels configuring each of the plurality of pixels may have a rotation angle rotated by a same angle with respect to a reference point within a corresponding subpixel, and pixel-based rotation angles of the light extraction portions in the one or more pixels included in each of the plurality of pixel groups may be equal to one another at a corresponding pixel group. For example, the plurality of subpixels may configure (or may be included in) each pixel of the plurality of pixels. For example, the light extraction portions may be in the one or more pixels. For example, the one or more pixels may be included in each pixel group of the plurality of pixel groups. For example, pixel-based rotation angles of the light extraction portions in the one or more pixels included in each pixel group (or one pixel group) of the plurality of pixel groups may be equal to pixel-based rotation angles of the light extraction portions in the one or more pixels included in another pixel group of the plurality of pixel groups.

According to one or more example embodiments of the present disclosure, pixel group-based rotation angles of the light extraction portions in each of the plurality of pixel groups included in each of the plurality of pixel blocks may differ from one another at a corresponding pixel block. For example, the light extraction portions may be in each of the plurality of pixel groups. For example, the plurality of pixel groups may be included in each of the plurality of pixel blocks. For example, pixel group-based rotation angles of the light extraction portions in each of the plurality of pixel groups, where the plurality of pixel groups are included in each of the plurality of pixel blocks, (the “pixel group-based rotation angles in each pixel block”) may differ from pixel group-based rotation angles of the light extraction portions in each of the plurality of pixel groups, where the plurality of pixel groups are included in another pixel block of the plurality of pixel blocks (the “pixel group-based rotation angles in another pixel block”). For example, pixel group-based rotation angles of the light extraction portions in each pixel block (or one pixel block) may differ from pixel group-based rotation angles of the light extraction portions in another pixel block.

According to one or more example embodiments of the present disclosure, the plurality of pixel groups may comprise two adjacent pixel groups, and pixel-based rotation angles of light extraction portions of two adjacent pixel groups in each of the plurality of pixel blocks may be within a range of more than 0 degrees and less than 60 degrees and may have a difference of 1 degree or more or 3 degrees or more within a range of more than 0 degrees and less than 60 degrees. In one or more aspects, the plurality of pixel groups may comprise the two adjacent pixel groups.

According to one or more example embodiments of the present disclosure, pixel block-based rotation angles of the light extraction portions in each of the plurality of pixel blocks may differ.

According to one or more example embodiments of the present disclosure, the light extraction portion in one of the plurality of subpixels and the light extraction portion of each of other subpixels of the plurality of subpixels may have rotated by different angles with respect to a reference point within a corresponding subpixel. For example, a light extraction portion in one subpixel of the plurality of subpixels may have rotated by a first angle with respect to a reference point within the one subpixel. A light extraction portion in each of the other subpixels of the plurality of subpixels may have rotated by a second angle with respect to a reference point within the corresponding subpixel of the other subpixels. The first angle may be different from the second angle.

According to one or more example embodiments of the present disclosure, the light extraction portions of the other subpixels of the plurality of subpixels may have rotated by a same angle with respect to the reference point.

According to one or more example embodiments of the present disclosure, the light extraction portion of the one of the plurality of subpixels may have rotated by an angle of more than 0 degrees and less than 60 degrees with respect to the reference point, and the light extraction portions of the other subpixels of the plurality of subpixels may have rotated by an angle of more than 0 degrees and less than 60 degrees with respect to the reference point.

According to one or more example embodiments of the present disclosure, the one of the plurality of subpixels may be a white subpixel, and the other subpixels of the plurality of subpixels may comprise a red subpixel, a blue subpixel, and a green subpixel.

According to one or more example embodiments of the present disclosure, rotation angles of the light extraction portions disposed at the white subpixels in two adjacent pixels among the plurality of pixels may differ.

According to one or more example embodiments of the present disclosure, the rotation angles of the light extraction portions disposed at the white subpixels in the two adjacent pixels among the plurality of pixels is within a range of more than 0 degrees and less than 60 degrees and have a difference of 1 degree or more or 3 degrees or more.

According to one or more example embodiments of the present disclosure, the convex portion surrounding one concave portion of the plurality of concave portions may have a hexagonal shape in a plan view.

The light emitting display apparatus according to one or more example embodiments of the present disclosure can be applied to or included in various electronic apparatuses. For example, the light emitting display apparatus according to one or more example embodiments of the present disclosure can be applied to or included in mobile devices, video phones, smart watches, watch phones, wearable devices, foldable devices, rollable devices, bendable devices, flexible devices, curved devices, electronic organizers, electronic books, portable multimedia players (PMPs), personal digital assistants (PDAs), motion pictures expert group audio layer 3 (MP3) players, mobile medical devices, desktop personal computers (PCs), laptop PCs, netbook computers, workstations, navigation apparatuses, automotive navigation apparatuses, automotive display apparatuses, TVs, wall paper display apparatuses, signage apparatuses, game machines, notebook computers, monitors, cameras, camcorders, and home appliances, or the like.

It will be apparent to those skilled in the art that various modifications and variations can be made in the present disclosure without departing from the spirit or scope of the present disclosure. Thus, it is intended that the present disclosure covers the modifications and variations of this disclosure provided they come within the scope of the appended claims and their equivalents.

What is claimed is:

1. A light emitting display apparatus, comprising:
a substrate;
a plurality of pixels including a plurality of subpixels on the substrate;
a light extraction portion disposed on the substrate and in each of the plurality of subpixels; and
a light emitting device layer on the light extraction portion,
wherein:
the light extraction portion comprises a plurality of concave portions and a convex portion between the plurality of concave portions; and
a tilt line passing through a center portion of each of the plurality of concave portions at one or more of the plurality of subpixels is inclined from a straight line parallel to a length direction of the substrate.

2. The light emitting display apparatus of claim 1, wherein an angle between the straight line and the tilt line is more than 0 degrees and less than 60 degrees.

3. The light emitting display apparatus of claim 1, wherein the light extraction portion has rotated with respect to a reference point within a corresponding subpixel.

4. The light emitting display apparatus of claim 1, wherein the light extraction portion has rotated by an angle of more than 0 degrees and less than 60 degrees with respect to the center portion of one of the plurality of concave portions of a corresponding subpixel.

5. The light emitting display apparatus of claim 1, wherein a tilt line passing through center portions of the plurality of concave portions in each of the plurality of subpixels is inclined by a different angle from the straight line.

6. The light emitting display apparatus of claim 5, wherein the tilt line passing through the center portions of the plurality of concave portions in each of the plurality of subpixels is inclined by a different angle within a range of more than 0 degrees and less than 60 degrees from the straight line.

7. The light emitting display apparatus of claim 1, wherein the light extraction portions of the plurality of subpixels have rotated by different angles with respect to reference points within corresponding subpixels.

8. The light emitting display apparatus of claim 7, wherein the light extraction portions of the plurality of subpixels have rotated by different angles within a range of more than 0 degrees and less than 60 degrees with respect to the reference points within the corresponding sub pixels.

9. The light emitting display apparatus of claim 1, further comprising a plurality of pixel blocks including a plurality of pixel groups,
wherein each of the plurality of pixel groups comprises one or more of the plurality of pixels.

10. The light emitting display apparatus of claim 9, wherein:
the one or more of the plurality of pixels comprise one or more pixels;
the light extraction portion in each of the plurality of subpixels configuring each of the plurality of pixels has a rotation angle rotated by a same angle with respect to a reference point within a corresponding subpixel; and
pixel-based rotation angles of the light extraction portions in the one or more pixels included in each of the plurality of pixel groups are equal to one another at a corresponding pixel group.

11. The light emitting display apparatus of claim 10, wherein pixel group-based rotation angles of the light extraction portions in each of the plurality of pixel groups included in each of the plurality of pixel blocks differ from one another at a corresponding pixel block.

12. The light emitting display apparatus of claim 11, wherein:
the plurality of pixel groups comprise two adjacent pixel groups; and
pixel-based rotation angles of the light extraction portions of the two adjacent pixel groups in each of the plurality of pixel blocks is within a range of more than 0 degrees and less than 60 degrees and have a difference of 1 degree or more or 3 degrees or more.

13. The light emitting display apparatus of claim 9, wherein pixel block-based rotation angles of the light extraction portions in each of the plurality of pixel blocks differ.

14. The light emitting display apparatus of claim 1, wherein the light extraction portion in one of the plurality of subpixels and the light extraction portion of each of other subpixels of the plurality of subpixels have rotated by different angles with respect to a reference point within a corresponding subpixel.

15. The light emitting display apparatus of claim 14, wherein the light extraction portions of the other subpixels of the plurality of subpixels have rotated by a same angle with respect to the reference point.

16. The light emitting display apparatus of claim 14, wherein the light extraction portion of the one of the plurality of subpixels has rotated by an angle of more than 0 degrees and less than 60 degrees with respect to the reference point, and
wherein the light extraction portions of the other subpixels of the plurality of subpixels have rotated by an angle of more than 0 degrees and less than 60 degrees with respect to the reference point.

17. The light emitting display apparatus of claim 14, wherein the one of the plurality of subpixels is a white subpixel, and
wherein the other subpixels of the plurality of subpixels comprise a red subpixel, a blue subpixel, and a green subpixel.

18. The light emitting display apparatus of claim 17, wherein rotation angles of the light extraction portions disposed at the white subpixels in two adjacent pixels among the plurality of pixels differ.

19. The light emitting display apparatus of claim 18, wherein the rotation angles of the light extraction portions disposed at the white subpixels in the two adjacent pixels among the plurality of pixels is within a range of more than 0 degrees and less than 60 degrees and have a difference of 1 degree or more or 3 degrees or more.

20. The light emitting display apparatus of claim 1, wherein the convex portion surrounding one of the plurality of concave portions has a hexagonal shape in a plan view.
